(19) United States
(12) Patent Application Publication
(10) Pub. No.: US 2026/0206262 A1
(43) Pub. Date: Jul. 16, 2026

(54) NANOSTRUCTURE FIELD-EFFECT TRANSISTOR DEVICES AND METHODS OF FORMING

(71) Applicant: Taiwan Semiconductor Manufacturing Co., Ltd., Hsinchu (TW)

(72) Inventors: Chien-I Kuo, Zhubei (TW); Chii-Horng Li, Zhubei (TW); Heng-Wen Ting, Pingtung (TW)

(21) Appl. No.: 19/196,592

(22) Filed: May 1, 2025

Related U.S. Application Data
(60) Provisional application No. 63/745,037, filed on Jan. 14, 2025.

(51) Int. Cl. H10D 30/69; H10D 30/00; H10D 30/01; H10D 30/43; H10D 62/00; H10D 62/10; H10D 62/13; H10D 64/01; H10D 84/01; H10D 84/83

(52) U.S. Cl. CPC H10D 30/797; H10D 30/014; H10D 30/0191; H10D 30/43; H10D 30/502; H10D 62/021; H10D 62/121; H10D 62/151; H10D 64/017; H10D 84/013; H10D 84/832

(57) ABSTRACT

A dielectric layer is formed at a bottom of a source/drain opening for a p-type source/drain region of a nanostructure field-effect transistor (NSFET) device. Next, a source/drain region with a multi-layered structure is formed in the source/drain opening over the dielectric layer. In some examples, forming the source/drain region includes forming a first epitaxial material in the source/drain opening, where the first epitaxial material includes discrete portions disposed along sidewalls of a channel material of the NSFET device exposed to the source/drain opening. A second epitaxial material is then formed on the first epitaxial material and partially fills the source/drain opening. The second epitaxial material may extend continuously from a first discrete portion of the first epitaxial material to a second discrete portion of the first epitaxial material. A third epitaxial material is then formed on the second epitaxial material to fill the source/drain opening.

### PRIORITY CLAIM AND CROSS-REFERENCE

This application claims priority to U.S. Provisional Application No. 63/745,037, filed Jan. 14, 2025 and entitled “Channel Strain Enhancement by Novel PMOS Source-Drain Design,” which application is incorporated herein by reference.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 5C, 6A, 6B, 6C, 7A, 7B, 7C, 8A, 8B, 8C, 9A, 9B, 9C, 10A, 10B, 10C, 11, 12, 13, 14A, 14B, 14C, 15A, 15B, 16A, 16B, 17A, and 17B are cross-sectional views of a portion of a nanostructure field-effect transistor (NSFET) device at various stages of manufacturing, in accordance with an embodiment.

FIG. 18 illustrates a cross-sectional view of a portion of an NSFET device at a certain stage of manufacturing, in accordance with an embodiment.

FIG. 19 illustrates a cross-sectional view of a portion of an NSFET device at a certain stage of manufacturing, in accordance with an embodiment.

FIG. 20 illustrates a cross-sectional view of a portion of an NSFET device at a certain stage of manufacturing, in accordance with an embodiment.

FIG. 21 illustrates a cross-sectional view of a portion of an NSFET device at a certain stage of manufacturing, in accordance with an embodiment.

FIG. 22 illustrates a cross-sectional view of a portion of an NSFET device at a certain stage of manufacturing, in accordance with an embodiment.

FIG. 23 illustrates a cross-sectional view of a portion of an NSFET device at a certain stage of manufacturing, in accordance with an embodiment.

FIG. 24 illustrates a cross-sectional view of a portion of an NSFET device at a certain stage of manufacturing, in accordance with an embodiment.

FIG. 25 illustrates a cross-sectional view of a portion of an NSFET device at a certain stage of manufacturing, in accordance with an embodiment.

FIG. 26 illustrates a cross-sectional view of a portion of an NSFET device at a certain stage of manufacturing, in accordance with an embodiment.

FIG. 27 illustrates a cross-sectional view of a portion of an NSFET device at a certain stage of manufacturing, in accordance with an embodiment.

FIG. 28 illustrates a cross-sectional view of a portion of an NSFET device at a certain stage of manufacturing, in accordance with an embodiment.

FIG. 29 illustrates a cross-sectional view of a portion of an NSFET device at a certain stage of manufacturing, in accordance with an embodiment.

FIG. 30 illustrates a cross-sectional view of a portion of an NSFET device at a certain stage of manufacturing, in accordance with an embodiment.

FIG. 31 illustrates a cross-sectional view of a portion of an NSFET device at a certain stage of manufacturing, in accordance with an embodiment.

FIGS. 32A and 32B together illustrate a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

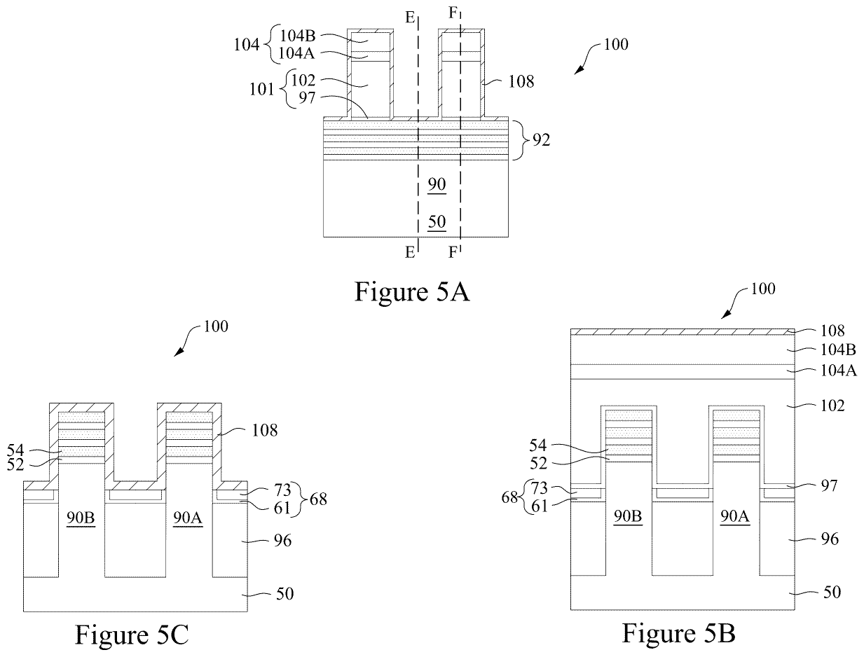

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise specified, the same or similar reference numeral in different figures refer to the same or similar component formed by a same or similar formation process using a same or similar material(s). In addition, figures with the same numeral but different alphabets (e.g., FIGS. 5A-5C) illustrate different views of the device at the same stage of processing.

In some embodiments, a dielectric layer is formed at a bottom of a source/drain opening for a p-type source/drain region of a nanostructure field-effect transistor (NSFET) device. Next, a source/drain region with a multi-layered structure is formed in the source/drain opening over the dielectric layer. In some embodiments, forming the source/drain region comprises forming a first epitaxial material in the source/drain opening, where the first epitaxial material comprises discrete portions disposed along sidewalls of a channel material exposed to the source/drain opening. A second epitaxial material is then formed on the first epitaxial material and partially fills the source/drain opening. The second epitaxial material may extend continuously from a first discrete portion of the first epitaxial material to a second discrete portion of the first epitaxial material. A third epitaxial material is then formed on the second epitaxial material to fill the source/drain opening. In some embodiments, the first epitaxial material is boron-doped silicon, the second epitaxial material is boron-doped silicon germanium, and the third epitaxial material is boron-doped silicon germanium having a different atomic percentage of germanium than the second epitaxial material.

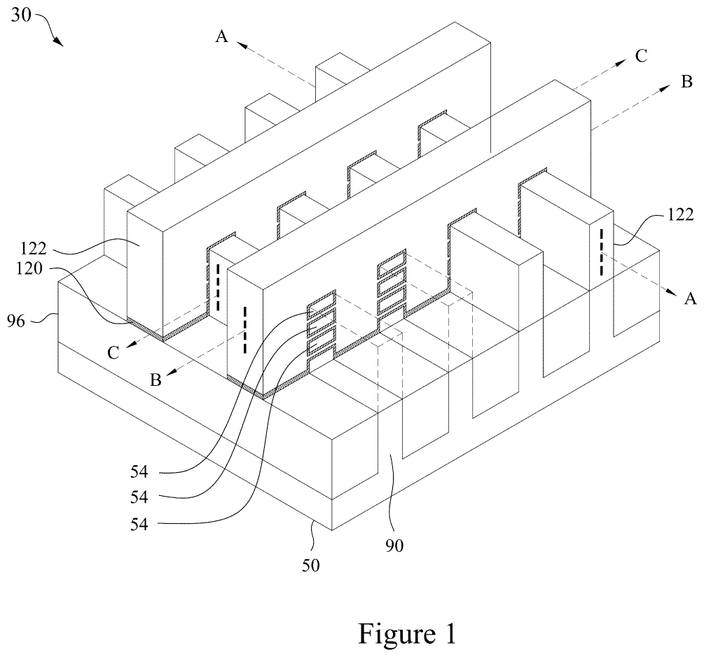

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the fin 90 and in a direction of, for example, a current flow between the source/drain regions 112 of the NSFET device. Cross-section B-B is perpendicular to cross-section A-A, and is along a longitudinal axis of the gate electrode 122 and in a direction, for example, perpendicular to the direction of current flow between the source/drain regions 112 of the NSFET device 30. Cross-section C-C is parallel to cross-section B-B and extends through source/drain regions 112 of the NSFET device. Subsequent figures may refer to these reference cross-sections for clarity.

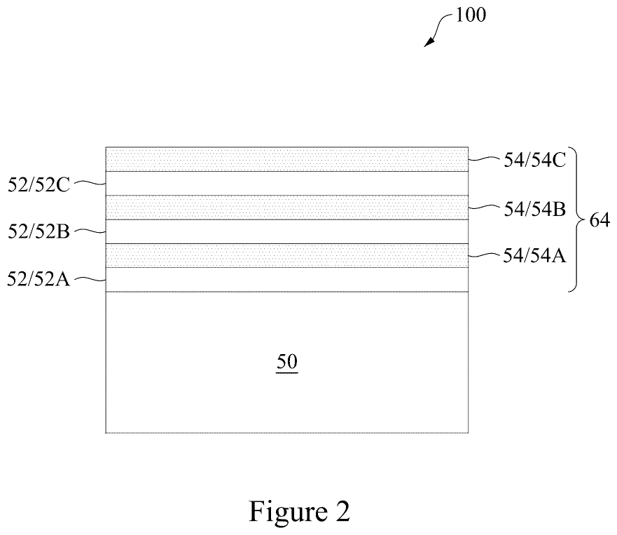

FIGS. 2, 3A, 3B, 4A, 4B, 5A, 5B, 5C, 6A, 6B, 6C, 7A, 7B, 7C, 8A, 8B, 8C, 9A, 9B, 9C, 10A, 10B, 10C, 11, 12, 13, 14A, 14B, 14C, 15A, 15B, 16A, 16B, 17A, and 17B are cross-sectional views of a portion of a nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the semiconductor materials illustrated in FIG. 2 are merely non-limiting examples. Other numbers of layers are also possible and are fully intended to be included within the scope of the present disclosure.

In some embodiments, the first semiconductor material 52 is a first type of epitaxial material, such as silicon germanium (SiₓGe₁₋ₓ, where x can be in the range of 0 to 1), and the second semiconductor material 54 is a second type of epitaxial material, such as silicon. The multi-layer stack 64 (which may also be referred to as an epitaxial material stack) will be patterned to form channel regions of an NSFET in subsequent processing. In particular, the multi-layer stack 64 will be patterned and etched to form nanostructures (e.g., nanosheets or nanowires), with the channel regions of the resulting NSFET including multiple horizontally extending nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

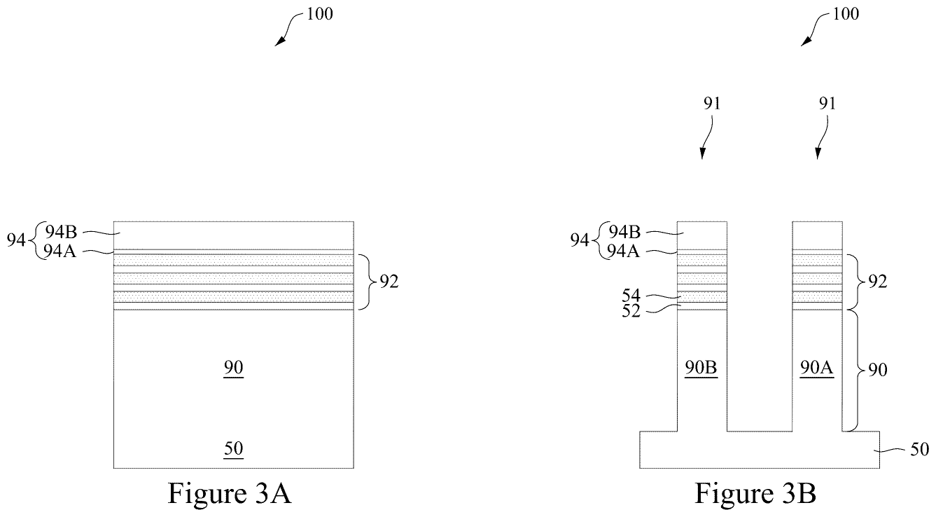

FIGS. 3A, 3B, 4A, 4B, 5A, 5B, 5C, 6A, 6B, 6C, 7A, 7B, 7C, 8A, 8B, 8C, 9A, 9B, 9C, 10A, 10B, 10C, 11, 12, 13, 14A, 14B, 14C, 15A, 15B, 16A, 16B, 17A, and 17B are cross-sectional views of the NSFET device 100 at subsequent stages of manufacturing, in accordance with an embodiment. FIGS. 3A, 4A, 5A, 6A, 7A, 8A, 9A, 10A, 11, 12, 13, 14A, 15A, 16A, and 17A are cross-sectional views along cross-section A-A in FIG. 1. FIGS. 3B, 4B, 5B, 6B, 7B, 8B, 9B, 10B, 14B, 15B, 16B, and 17B are cross-sectional views along cross-section B-B in FIG. 1. FIGS. 5C, 6C, 7C, 8C, 9C, 10C, and 14C are cross-sectional views along cross-section C-C in FIG. 1. The number of fins and the number of gate structures illustrated in the figures are merely non-limiting examples, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etching process, such as a reactive ion etch (RIE), neutral beam etch (NBE), the like, or a combination thereof. The etching is an anisotropic etching process, in some embodiments. After the etching process, the patterned multi-layer stack 64 forms the layer stack 92, and the patterned portion of the substrate 50 forms the fin 90 (e.g., 90A or 90B), as illustrated in FIGS. 3A and 3B. The remaining (e.g., un-patterned) portion of the substrate 50 is referred to as the substrate 50 in FIGS. 3A and 3B and subsequent figures. Therefore, in the illustrated embodiment, the layer stack 92 also includes alternating layers of the first semiconductor material 52 and the second semiconductor material 54. The fin 90 is formed of a same material as the substrate 50. In the example of FIGS. 3A and 3B, fins 90A and 90B are formed to extend parallel to each other.

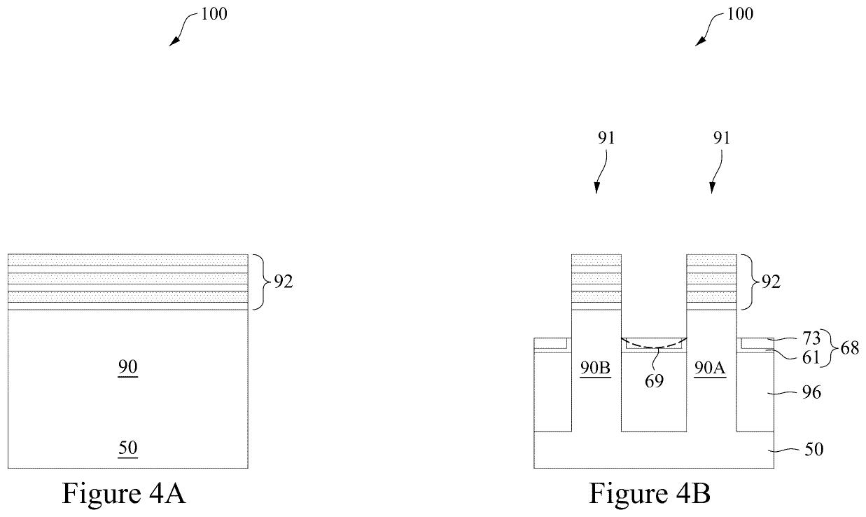

Next, in FIGS. 4A and 4B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material disposed over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

Still referring to FIGS. 4A and 4B, an STI protection structure 68 is formed on the upper surfaces of the STI regions 96. The STI protection structure 68 may include a liner layer 61 and a hard mask layer 73. The STI protection structure 68 protects portions of the STI regions 63 disposed directly under the subsequently formed dummy gate structure during a subsequent sheet formation process (e.g., an etching process). Details are discussed hereinafter.

In some embodiment, the liner layer 61 is formed over the layer stacks 92 and over the STI regions 96. The liner layer 61 may be a suitable dielectric material such as silicon oxide, and may be formed using a suitable deposition method such as CVD, atomic layer deposition (ALD), or the like. Besides silicon oxide, other suitable material, such as a dielectric material that provides high etching selectivity from the layer stack 92 and the subsequently formed hard mask layer 73 may also be used.

Next, the hard mask layer 73 is formed over the liner layer 61. The hard mask layer 73 is formed of a material different from the liner layer 61 and the STI regions 96. In some embodiments, the material of the hard mask layer 73 is chosen to provide high etching selectivity from the material of the STI regions 96. In an embodiment, the STI regions 96 is formed of silicon oxide, and the hard mask layer 73 is formed of silicon nitride. Besides silicon nitride, other suitable materials, such as silicon oxynitride, silicon oxycarbonitride, or the like, may also be used to form the hard mask layer 73. A suitable formation method, such as CVD, plasm-enhanced CVD (PECVD), or the like, may be used to form the hard mask layer 73.

Next, a plurality of etching processes, which may include dry etching, wet etching, combinations thereof, or the like, are performed to remove portions of the liner layer 61 and the hard mask layer 73 from the upper surfaces and the sidewalls of the layer stacks 92. The remaining portions of the liner layer 61 and the hard mask layer 73 on the upper surfaces of the STI regions 96 form the STI protection structure 68.

In the example of FIG. 4B, the liner layer 61 of the STI protection structure 68 extends along the sidewalls and the bottom surface of the hard mask layer 73 of the STI protection structure 68. In some embodiments, the upper surface of the STI protection structure 68 is a flat surface, as illustrated in FIG. 4B. In some embodiments, the upper surface of the STI protection structure 68 between adjacent fin structures 91 is a concave surface, as illustrated by the dashed line 69 in FIG. 4B. Subsequent drawings use the example where the STI protections structure 68 has a flat surface, with the understanding that the upper surface of the STI protection structure 68 may have other shapes, such as a concave shape, or a convex shape. These and other variations are fully intended to be included within the scope of the present disclosure.

Next, in FIGS. 5A-5C, a dummy dielectric layer 97 is formed over the STI protection structure 68 and along the sidewalls and the top surfaces of the fin structure 91. The dummy dielectric layer 97 may be, for example, silicon oxide, silicon nitride, a combination thereof, or the like, and may be deposited or thermally grown according to acceptable techniques.

Next, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectric 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. Each dummy gate 102 and the underlying dummy gate dielectric 97 are collectively referred to as a dummy gate structure 101.

Next, a gate spacer layer 108 is formed by conformally depositing an insulating material over the layer stacks 92, the STI protection structure 68, and the dummy gate structures 101. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 5B and 5C illustrate cross-sectional views of the NSFET device 100 in FIG. 5A along cross-sections F-F and E-E in FIG. 5A, respectively. The cross-sections F-F and E-E correspond to cross-sections B-B and C-C in FIG. 1, respectively. Note that FIG. 5A illustrates the cross-sectional view along the longitudinal direction (e.g., a current flow direction) of one of the fins 90, the cross-sectional views along the longitudinal directions (e.g., current flow directions) of other fins 90 are the same or similar unless otherwise specified. In addition, FIG. 5A illustrates two dummy gate structures 101 as a non-limiting example, the number of dummy gate structures 101 over the fins 90 may be any suitable number.

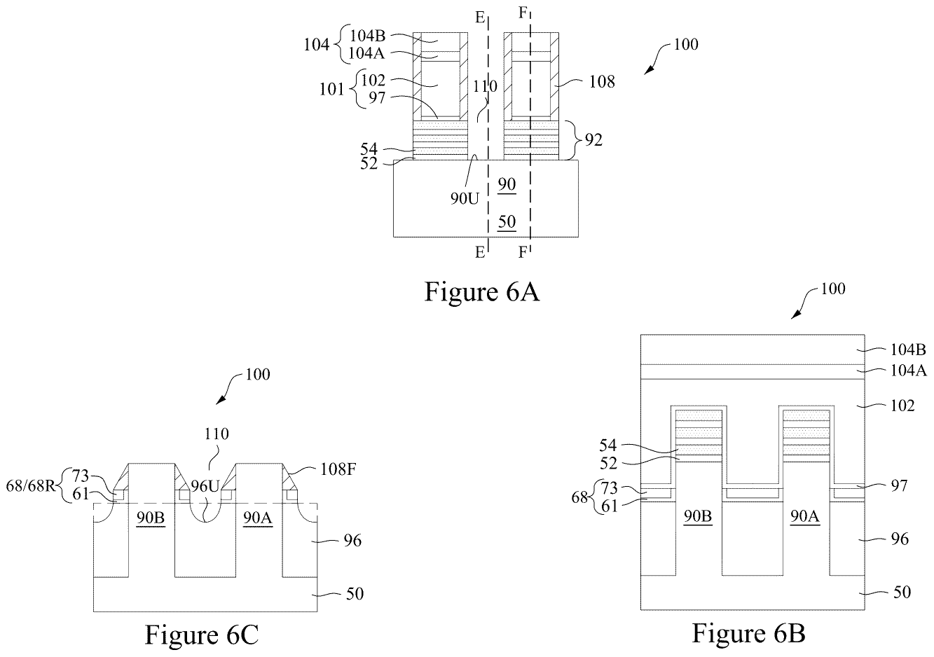

Next, in FIGS. 6A-6C, the gate spacer layers 108 are etched by an anisotropic etching process to form gate spacers 108. The anisotropic etching process may remove horizontal portions of the gate spacer layer 108 (e.g., portions over the STI regions 96 and the dummy gates 102), with remaining vertical portions of the gate spacer layer 108 along sidewalls of the dummy gate structures 101 forming the gate spacers 108. In addition, the remaining vertical portions of the gate spacer layer 108 along sidewalls of the fins 90 form fin spacers 108F (see, e.g., FIG. 6C).

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities of from about 1E15 /cm³ to about 1E16/cm³. An anneal process may be used to activate the implanted impurities.

Next, openings 110 (which may also be referred to as recesses or source/drain openings) are formed in the layer stacks 92. The openings 110 may extend through the layer stacks 92 and into the fins 90. The openings 110 may be formed by an anisotropic etching process using, e.g., the dummy gate structures 101 and the gate spacers 108 as an etching mask. Bottoms of the openings 110 expose upper surfaces 90U of the fins 90. Sidewalls of the openings 110 expose the first semiconductor material 52 and the second semiconductor material 54.

In the example of FIG. 6C, the anisotropic etching process for forming the source/drain openings 110 removes portions of the STI protection structure 68 that are disposed beyond sidewalls of the fin spacers 108F, and also removes portions of the underlying STI regions 96, thereby resulting in recesses in the STI regions 96. FIG. 6C shows curved (e.g., concave) upper surfaces 96U of the STI regions 96 due to the etching of the STI regions 96. In some embodiments, the anisotropic etching process for forming the source/drain opening 110 does not remove the STI regions 96, and therefore, the upper surface 96U of the STI regions 96 is substantially level, as indicated by the dashed line in FIG. 6C. The subsequent figures use the curved upper surface 96U as a non-limiting example, with the understanding that the upper surface 96U may be level. These and other variations are fully intended to be included within the scope of the present disclosure. Note that as illustrated in FIG. 6B, portions of the STI protection structure 68 and portions of the STI regions 96 that are disposed under (e.g., directly under) the dummy gate structures 101 are shielded from the anisotropic etching process, thus remain intact. In some embodiments, the anisotropic etching process for forming the source/drain openings 110 does not remove the STI regions 96 disposed between adjacent fins 90, and the upper surfaces of the STI regions 96 may not have the recesses as shown in FIG. 6C, and may remain substantially unchanged before and after the anisotropic etching process.

As illustrated in FIG. 6C, portions of the STI protection structure 68 remain under the fin spacers 108F, and are referred to as remaining portions 68R of the STI protection structure 68. The remaining portions 68R of the STI protection structure 68 protect the fins 90 from over-etching by the anisotropic etching process for forming the source/drain openings 110. Without the remaining portions 68R of the STI protection structure 68, over-etching by the anisotropic etching process may expose and/or remove portions of the fins 90 disposed below the fin spacers 108F. The un-intended removal of the portions of the fins 90 by the over-etching may cause the fins 90 to collapse, and/or may cause un-intended growth of epitaxial source/drain material from the un-intendedly exposed portions of the fins 90 during the subsequent source/drain regions formation process. The un-intended growth of epitaxial source/drain material between adjacent fins 90 may cause electrical short between the adjacent source/drain regions, thus causing device failure. The disclosed method herein, by having the remaining portions 68R of the STI protection structure 68, avoids the above over-etching related issues, thereby preventing or reducing the likelihood of device failure and improving production yield. This illustrate an advantage of the presently disclosure.

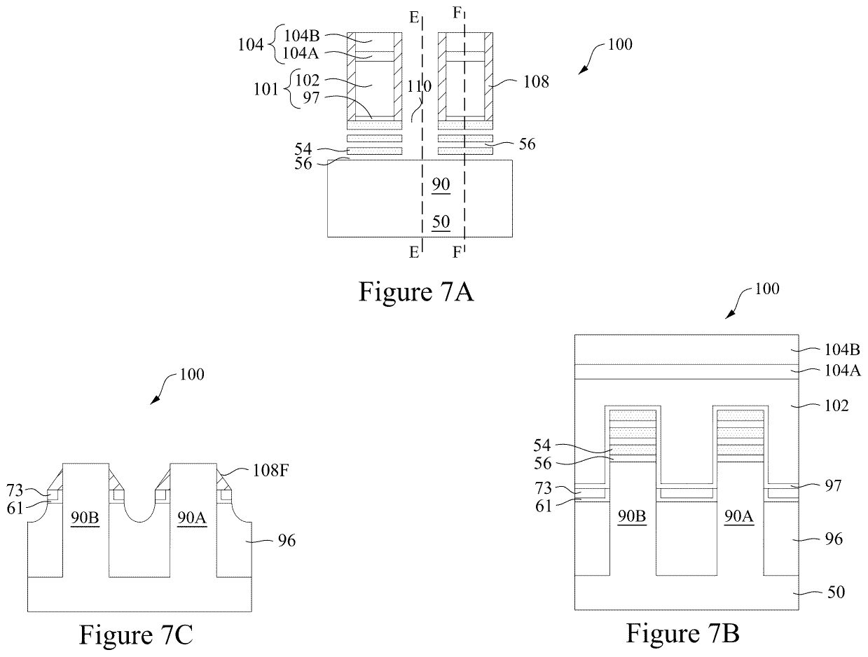

Next, in FIGS. 7A-7C, the first semiconductor material 52 under the dummy gate structures 101 and exposed by the openings 110 are removed. The first semiconductor material 52 may be removed by performing an isotropic etching process such as wet etching or the like using etchant(s) which is selective to the materials of the first semiconductor material 52, while the second semiconductor material 54, the fins 90, and the STI regions 96 remain relatively unetched as compared to the first semiconductor material 52. In embodiments in which the first semiconductor material 52 include, e.g., SiGe, and the second semiconductor material 54 include, e.g., Si or SiC, tetramethylammonium hydroxide (TMAH), ammonium hydroxide (NH₄OH), or the like may be used to selectively remove the first semiconductor material 52. After the first semiconductor material 52 is removed, gaps 56 (e.g., empty spaces) are formed between adjacent layers of the second semiconductor material 54, and between the fin 90 and a lowermost layer of the second semiconductor material 54.

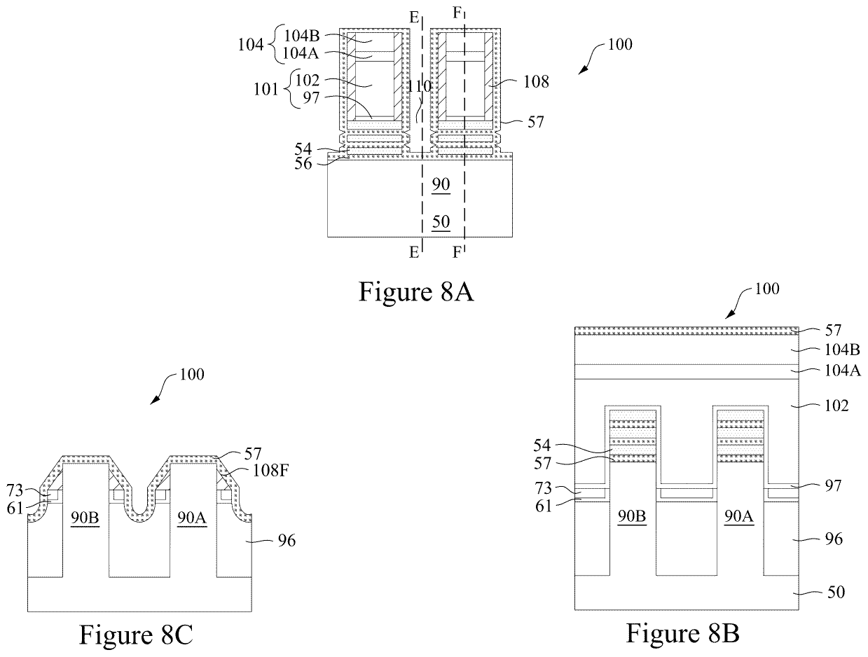

Next, in FIGS. 8A-8C, a disposable material 57 (may also be referred to as a sacrificial material) is deposited in the openings 110 to line the sidewalls and bottoms of the openings 110. The disposable material 57 also fills the gaps 56. The disposable material 57 may be deposited by a conformal deposition process, such as CVD, ALD, or the like. The disposable material 57 may be a dielectric material, such as silicon oxide (SiO), silicon oxynitride (SiON), aluminum oxide (Al₂O₃), combinations thereof, or the like. These materials are selected for their properties, such as etching selectivity, which allows for precise removal during the manufacturing process without adversely affecting the adjacent and underlying structures. The choice of the disposable material 57 may depend on the specific requirements of the semiconductor device being fabricated and the target electrical and physical properties of the final product.

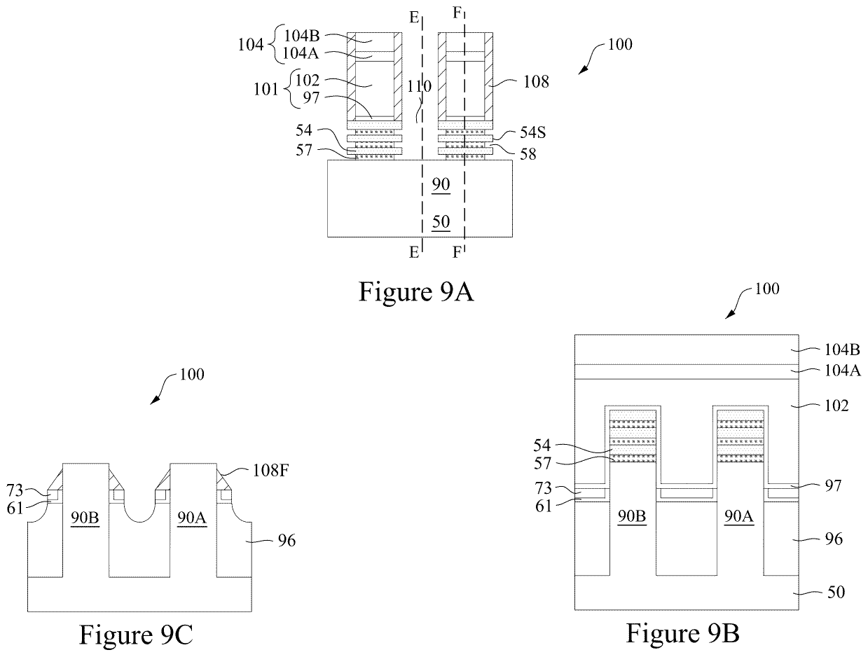

Next, in FIGS. 9A-9C, the disposable material 57 disposed outside the gaps 56 are removed, and sidewalls of the remaining portions of the disposable material 57 are recessed from respective sidewalls 54S of the second semiconductor material 54 to form sidewall recesses 58.

In some embodiments, an anisotropic etching process, e.g. a dry etching process such as a plasma etching process, is performed to remove the disposable material 57 disposed outside the gaps 56. Next, an isotropic etching process, such as a wet etching process, is performed to recess the remaining portions of the disposable material 57 to form the sidewall recesses 58. The dry etching process and the wet etching process may use etchants selective to the disposable material 57, such that the disposable material 57 is etched without substantially attacking other material(s) and/or structures. In some embodiments, multiple etching cycles, where each etching cycle includes the dry etching process followed by the wet etching process, are performed to remove the disposable material 57 and to form the sidewall recesses 58. The etching cycles are repeated until sidewalls of the disposable material 57 are recessed past sidewalls 54S of the second semiconductor material 54. In some embodiments, the disposable material 57 is etched by a wet etching process using hydrogen fluoride, diluted hydrogen fluoride, another fluorine-based etchant, or the like as an etchant. The wet etching process is performed until sidewalls of the disposable material 57 are recessed past sidewalls 54S of the second semiconductor material 54. The remaining portions of the disposable material 57, which are interposed between layers of the second semiconductor material 54, or between the fins 90 and a lowermost layer of the second semiconductor material 54, are referred to as disposable oxide interposers (DOIs). This process of replacing the first semiconductor material 52 with the DOIs may be referred to as a DOI process. In the subsequent sheet formation process, the DOIs are selectively removed to release the layers of the second semiconductor material 54 to form nanostructures 54 (e.g., nanosheets, or nanowires). The nanostructures 54 function as the channel regions of the NSFET device formed, and therefore, the second semiconductor material 54 may also be referred to as a channel material. The first semiconductor material 52 may also be referred to as a dummy material.

Replacing the first semiconductor material 52 with the disposable material 57 in the DOI process may provide advantages. To appreciate the advantages, consider a reference manufacturing process where the first semiconductor material 52 is not replaced with the disposable material 57. In subsequent source/drain formation steps, one or more high temperature processes may be performed to, for example, activate the dopants in the source/drain regions. When the first semiconductor material 52 (e.g., SiGe) is exposed to high temperatures, germanium in the first semiconductor material 52 may diffuse into and mix with the second semiconductor material 54 (e.g., Si), which is referred to as intermixing between germanium and silicon. Intermixing may increase roughness at interfaces between the first semiconductor material 52 and the second semiconductor material 54, and may cause manufacturing defects that degrade the performance of the resulting devices. By replacing the first semiconductor material 52 with the disposable material 57 prior to the high temperature processes (e.g., source/drain annealing), intermixing is avoided, and manufacturing defects can be reduced and device performance can be improved. In addition, the material (e.g., SiO) of the DOIs provide excellent etching selectivity (e.g., higher than 10,000) from the material (e.g. Si) of the second semiconductor material 54, thus allowing for selective removal of the DOIs in the sheet formation process with little or no damage to the nanostructures 54.

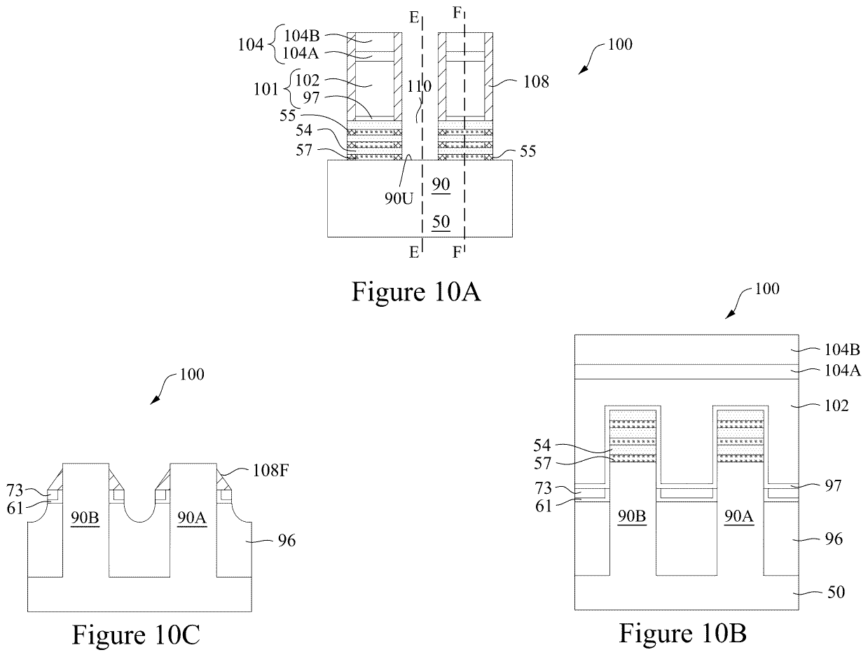

Next, in FIGS. 10A-10C, inner spacers 55 are formed in the sidewall recesses 58. In some embodiments, to form the inner spacers 55, an inner spacer layer is formed (e.g., conformally) in the openings 110. The inner spacer layer also fills the sidewall recesses 58 of the sacrificial material 57. The inner spacer layer may be a suitable dielectric material, such as silicon carbonitride (SiCN), silicon oxycarbonitride (SiOCN), or the like, formed by a suitable deposition method such as PVD, CVD, ALD, or the like. Next, an etching process, such as an anisotropic etching process, is performed to remove portions of the inner spacer layers disposed outside the sidewall recesses 58 of the sacrificial material 57. The remaining portions of the inner spacer layers (e.g., portions disposed inside the sidewall recesses 58 of the sacrificial material 57) form inner spacers 55. As illustrated in FIG. 10A, the openings 110 expose sidewalls of the second semiconductor material 54 and expose upper surfaces 90U of the fins 90.

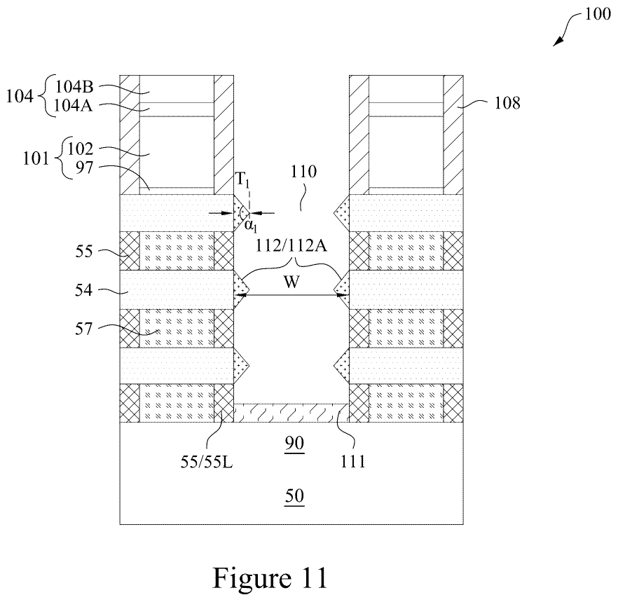

Next, as illustrated in FIGS. 11-13, a dielectric layer 111 is formed at the bottoms of the openings 110, and source/drain regions 112, which include three sublayers of epitaxial materials 112A, 112B, and 112C, are formed in the openings 110 on the dielectric layer 111. FIGS. 11-13 illustrate the processing steps for forming of the epitaxial materials 112A, 112B, and 112C, respectively. Details are discussed hereinafter. Note that for simplicity, FIGS. 11-13 illustrate a portion of the NSFET device 100 that includes two adjacent dummy gate structures 101 and the source/drain region 112 formed in-between.

In the discussion herein, source/drain region(s) may refer to a source or a drain, individually or collectively dependent upon the context. In the illustrated embodiments, the source/drain regions 112 are formed of epitaxial materials, and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

Referring now to FIG. 11, the dielectric layer 111 is formed at the bottoms of the openings 110. The dielectric layer 111 may be a suitable dielectric material such as silicon oxide, silicon nitride, or the like, formed by a suitable formation method. In the illustrated embodiments, the thickness of the dielectric layer 111 is smaller than the high of the inner spacer 55, such that an upper surface of the dielectric layer 111 is closer to the substrate 50 than an upper surface of a lowermost inner spacer 55L. In other words, the upper surface of the dielectric layer 111 is between a lower surface and an upper surface of the lowermost inner spacer 55L. This ensures that the dielectric layer 111 does not cover the sidewalls of the second semiconductor material 54 exposed to the openings 110.

In some embodiments, the dielectric layer 111 helps to reduce leakage current and/or reduce the parasitic capacitance (e.g., the gate-to-source/drain capacitance, and/or the source/drain-to-substrate capacitance) of the NSFET device formed, thereby improving the device performance. However, for devices without the presently disclosed source/drain regions, the dielectric layer 111 may degrade the stress exerted by the source/drain regions 112 to the channel regions. The presently disclosed source/drain regions 112, with the unique structures for the source/drain regions 112, provide enhanced channel strain for p-type NSFET devices to overcome the challenge (e.g., degraded channel stress) produced by the dielectric layer 111. As a result, increased carrier mobility (e.g., hole mobility) and reduced channel resistance are achieved.

Next, an epitaxial material 112A (may also be referred to as a first sublayer of the source/drain regions 112) is formed (e.g., selectively formed) on the sidewalls of the second semiconductor material 54 exposed to the openings 110.

In some embodiments, the epitaxial material 112A is epitaxially grown in the openings 110. The epitaxial material 112A may include any acceptable material appropriate for p-type devices. For example, the epitaxial material 112A may include material(s) exerting a compressive strain in the channel regions and may include a p-type dopant. In the illustrated embodiments, the epitaxial material 112A is boron-doped silicon (Si:B). A concentration of the dopant (e.g., boron) in the epitaxial material 112A may be between about 1E20/cm³ and about 1E22/cm³, as an example.

The epitaxial process for forming the epitaxial material 112A is performed using a gas source that includes a silicon-containing gas, a boron-containing gas, and a growth-rate control gas, in some embodiments. The silicon-containing gas may be, e.g., SiH₄ or SiH₂Cl₂. The boron-containing gas may be, e.g., BH₃, B₂H₆, or BCl₃. The growth-rate control gas may be, e.g., HCl, which is used to control the growth rate of the epitaxial material 112A. In some embodiments, a carrier gas, such as H₂, is also used in the gas source. The epitaxial process for forming the epitaxial material 112A may be performed at a temperature between about 400° C. and about 850° C., and at a pressure between about 4 torr and about 300 torr.

As illustrated in FIG. 11, the epitaxial material 112A is selectively formed on the sidewalls of the second semiconductor material 54 exposed to the openings 110, and is not formed on surfaces of, e.g., the inner spacers 55 and the gate spacers 108. Due to the selective growth, the epitaxial material 112A comprises discrete (e.g., separate) portions that are disposed on respective sidewalls of the second semiconductor material 54. A discrete portion of the epitaxial material 112A may have a triangular-shaped cross-section, with one side of the epitaxial material 112A extending along a sidewall of the second semiconductor material 54, and with the other two sides of the epitaxial material 112A facing the opening 110 and intersecting at an angle α₁. The angle α₁ may be between about 30 degrees and about 60 degrees. A thickness T₁ of the discrete portion of the epitaxial material 112A, measured between the sidewall of the second semiconductor material 54 and a vertex of the triangular-shaped cross-section, is between about 1 nm and about 10 nm. The thickness T₁ is smaller than half of the width W measured between opposing sidewalls of second semiconductor material 54 facing the opening 110, in the illustrated embodiments.

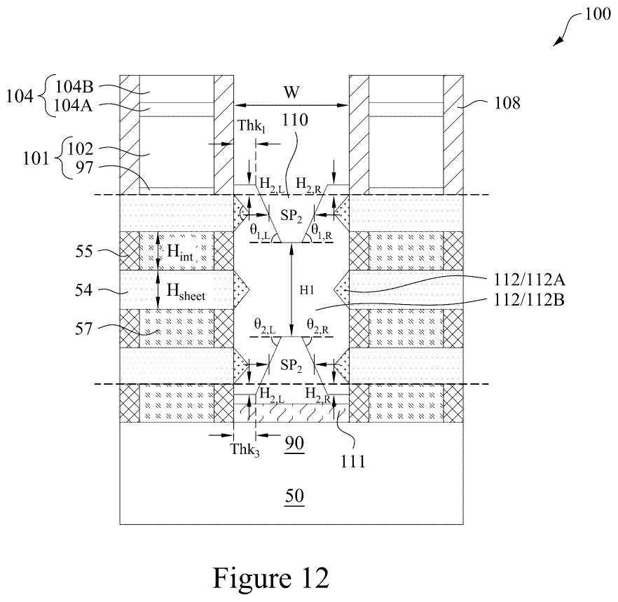

Next, in FIG. 12, an epitaxial material 112B (may also be referred to as a second sublayer of the source/drain regions 112) is formed on the exterior surfaces of the epitaxial material 112A exposed to the openings 110. The epitaxial material 112B may include material(s) exerting a compressive strain in the channel regions and may include a p-type dopant. In the illustrated embodiments, the epitaxial material 112B is boron-doped silicon germanium (Si₁₋ₓGeₓ:B). A concentration of the dopant (e.g., boron) in the epitaxial material 112B may be between about 1E19/cm³ and about 5E22/cm³, as an example. An atomic percentage (e.g., at %) of germanium in the epitaxial material 112B may be between about 3 at % and about 30 at %, as an example. In other words, the value of x in Si₁₋ₓGeₓ:B may be between about 0.03 and about 0.3.

In some embodiments, the epitaxial process for forming the epitaxial material 112B is performed using a gas source that includes a silicon-containing gas, a germanium-containing gas, a boron-containing gas, and a growth-rate control gas. The silicon-containing gas may be, e.g., SiH₄ or SiH₂Cl₂. The germanium-containing gas may be, e.g., GeH₄. The boron-containing gas may be, e.g., BH₃, B₂H₆, or BCl₃. The growth-rate control gas may be, e.g., HCl, which is used to control the growth rate of the epitaxial material 112B. In some embodiments, a carrier gas, such as H₂, is also used in the gas source. The epitaxial process for forming the epitaxial material 112B may be performed at a temperature between about 400° C. and about 850° C., and at a pressure between about 4 torr and about 300 torr.

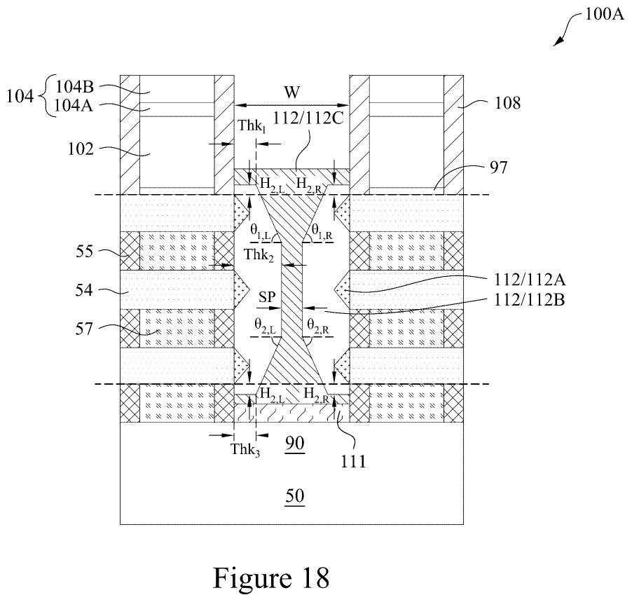

In some embodiments, after the epitaxial process for forming the epitaxial material 112B is finished, an etching process (also referred to as an etch-back process) or a thermal anneal process is performed to reshape (e.g., modify the shape) the epitaxial material 112B, such that the reshaped epitaxial material 112B has a designed shape, such as the shape illustrated in FIG. 12. Besides the shape illustrated in FIG. 12, the reshaped epitaxial material 112B may have other designed shapes, such as those discussed hereinafter with reference to FIGS. 18-28. The etching process and the thermal anneal process used for reshaping the epitaxial material 112B may be collectively referred to as a reshaping process.

In some embodiments, the reshaping process is performed with a gas source comprising a chlorine-containing gas and a silicon-containing gas, or with a gas source comprising a chlorine-containing gas and a germanium-containing gas. The silicon-containing gas may be, e.g., SiH₄ or SiH₂Cl₂. The germanium-containing gas may be, e.g., GeH₄. The chlorine-containing gas may be, e.g., HCl or Cl₂. In some embodiments, a carrier gas, such as H₂, is also used in the gas source. The reshaping process may be performed at a temperature between about 400° C. and about 1000° C., and at a pressure between about 4 torr and about 300 torr. In some embodiments, when the chlorine-containing gas is used (e.g., with a silicon-containing gas or with a germanium-containing gas) in the reshaping process, the reshaping process is referred to as an etching process (or an etch-back process). In some embodiments, the reshaping process is a thermal process performed using, e.g., H₂, and may be referred to as a thermal anneal process. In some embodiments, when the thermal anneal process is used as the reshaping process, the reshaped epitaxial material 112B tends to have curved (e.g., rounded) exterior surfaces instead of, e.g., linear exterior surfaces. Besides the above described parameters, other parameters, such as the duration of the epitaxial process for forming the epitaxial material 112B and/or the duration of the reshaping process, may be adjusted to achieve different designed shapes for the epitaxial material 112B, as skilled artisans readily appreciate.

In the example of FIG. 12, the epitaxial material 112B extends continuously along the opposing sidewalls of the opening 110, e.g., extending from the lowermost discrete portion of the epitaxial material 112A to the uppermost discrete portion of the epitaxial material 112A. The epitaxial material 112B grows from the exterior surfaces of the epitaxial material 112A toward the opening 110. In the example of FIG. 12, portions of the epitaxial material 112B along the opposing sidewalls of the opening 110 merge in the middle of the opening 110 and form a butterfly-shaped structure (also referred to as an X-shaped structure).

The butterfly-shaped epitaxial material 112B includes a left portion and a right portion that extend along the left sidewall and the right sidewall of the opening 110 (e.g., along exterior surfaces of the epitaxial material 112A and sidewalls of the inner spacers 55), respectively. The left portion and the right portion of the epitaxial material 112B are substantially symmetric, and merge in the middle (e.g., half way between the gate spacers 108 facing the opening 110) of the opening 110. The height H₁ of the epitaxial material 112B in the middle of the opening 110 (referred to as middle portion for simplicity) is smaller than that of the left portion (or the right portion) of the epitaxial material 112B. In some embodiments, the height H₁ of the middle portion of the epitaxial material 112B is smaller than a sum of the total height of the layers of the second semiconductor material 54 and the total height of the layers of the sacrificial material 57. In the example of FIG. 12, denote the height of each layer of the second semiconductor material 54 as Hₛₕₑₑₜ, and denote the height of each layer of the sacrificial material 57 as H_{∫¿.¿} Since there are three layers of the second semiconductor material 54 and three layer of the sacrificial material 57 in the example of FIG. 12, the following relation holds for FIG. 12: H₁<3Hₛₕₑₑₜ+3H_{∫¿¿}. The height H₁ of the epitaxial material 112B may be between about 1 nm and about 60 nm, as an example.

Still referring to FIG. 12, an uppermost surface of the left portion (or the right portion) of the epitaxial material 112B extends above an upper surface of an uppermost layer of the second semiconductor material 54 by a distance H_{2, L} (or H_{2, R}). Similarly, a lowermost surface of the left portion (or the right portion) of the epitaxial material 112B extends below a lower surface of a lowermost layer of the second semiconductor material 54 by the distance H_{2, L} (or H_{2, R}). The value of H_{2, L} (or H_{2, R}) may be between about 0 nm and about 10 nm. A width Thk₁ of the upper surface of the left portion (or the right portion) of the epitaxial material 112B is smaller than half of the width W measured between opposing sidewalls of second semiconductor material 54, such as between about 1 nm and about 10 nm. A width Thk₃ of the lower surface of the left portion (or the right portion) of the epitaxial material 112B is smaller than half of the width W, such as between about 1 nm and about 10 nm. A distance SP₂ between a sidewall of the left portion of the epitaxial material 112B and a sidewall of the right portion of the epitaxial material 112B, measured half way along the vertical direction between the upper surface (or the lower surface) of the left portion of the epitaxial material 112B and the upper surface (or the lower surface) of the middle portion of the epitaxial material 112B, is between about 2 nm and about 30 nm, in some embodiments. The angles between the horizontal direction and the exterior sidewalls of the left portion or the right portion of the epitaxial material 112B, denoted as ∅_{1, L}, ∅_{1, R}, ∅_{2, L}, and ∅_{2,R} in FIG. 12, are between about 30 degrees and about 90 degrees, in some embodiments.

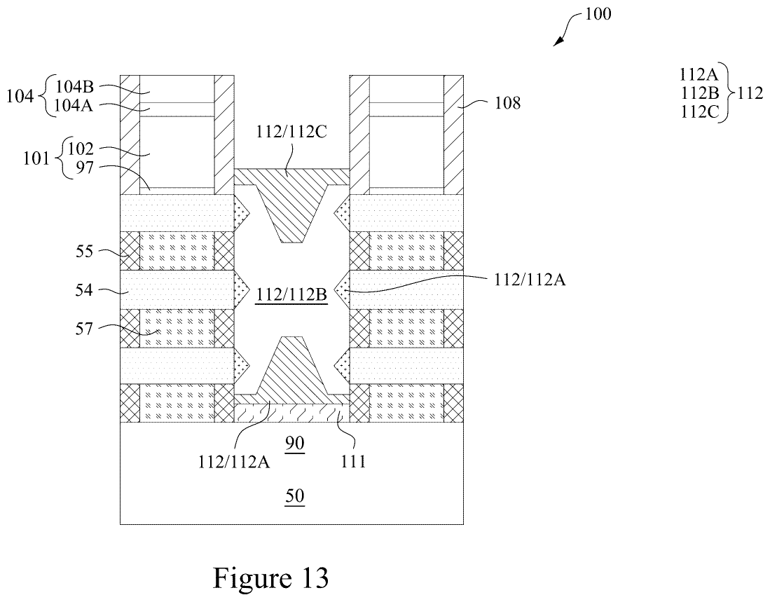

Next, in FIG. 13, an epitaxial material 112C (may also be referred to as a third sublayer of the source/drain regions 112) is formed on the epitaxial material 112B and fills the remaining portion of the openings 110. The epitaxial material 112C may include material(s) exerting a compressive strain in the channel regions and may include a p-type dopant. In the illustrated embodiments, the epitaxial material 112C is boron-doped silicon germanium (Si_{1-y}Ge_{y}:B). A concentration of the dopant (e.g., boron) in the epitaxial material 112C may be between about 1E19/cm³ and about 5E22/cm³, as an example. An atomic percentage (e.g., at %) of germanium in the epitaxial material 112C may be between about 40 at % and about 100 at %, as an example. In other words, the value of y in Si_{1-y}Ge_{y}:B is between about 0.4 and about 1.0.

Notably, the atomic percentage of germanium in the epitaxial material 112C is higher than that in the epitaxial material 112B. In other words, in embodiments where both the epitaxial materials 112B and 112C are boron-doped silicon germanium but with different germanium concentrations, an atomic ratio between a first constituent element (e.g., Ge) and a second constituent element (e.g., Si) of the epitaxial material 112C is different from that in the epitaxial material 112B. In embodiments where the atomic percentage of germanium in the epitaxial material 112C is 100 at %, the epitaxial material 112C is boron-doped germanium (Ge:B).

In some embodiments, the epitaxial process for forming the epitaxial material 112C is performed using a gas source that includes a silicon-containing gas, a germanium-containing gas, a boron-containing gas, and a growth-rate control gas. The silicon-containing gas may be, e.g., SiH₄ or SiH₂Cl₂. The germanium-containing gas may be, e.g., GeH₄. The boron-containing gas may be, e.g., BH₃, B₂H₆, or BCl₃. The growth-rate control gas may be, e.g., HCl, which is used to control the growth rate of the epitaxial material 112C. In some embodiments, a carrier gas, such as H₂, is also used in the gas source. In embodiments where the epitaxial material 112C is boron-doped germanium, the silicon-containing gas is omitted from the gas source. The epitaxial process for forming the epitaxial material 112C may be performed at a temperature between about 400° C. and about 850° C., and at a pressure between about 4 torr and about 300 torr.

As illustrated in FIG. 13, the epitaxial material 112C fills the spaces under and over the epitaxial material 112B, such as the space between the dielectric layer 111 and the epitaxial material 112B, and the space in the opening 110 over the epitaxial material 112B. The upper surface of the epitaxial material 112C may extend above the upper surface of the epitaxial material 112B. The epitaxial materials 112A, 112B, and 112C thus form the source/drain regions 112 with a tri-layered structure. Note that the source/drain regions 112 are p-type source/drain regions, and the NSFET device 100 is therefore a p-type NSFET device.

In the above example, the epitaxial source/drain regions 112 are in-situ doped with a dopant (e.g., boron). In some embodiments, each of the epitaxial materials 112A, 112B, and 112C is grown by the corresponding epitaxy process without the boron-containing gas, and after the epitaxial material 112A (or 112B, or 112C) is formed, the dopant (e.g., boron) is implanted into the epitaxial material using an implantation process, followed by an anneal. These and other variations are fully intended to be included within the scope of the present disclosure.

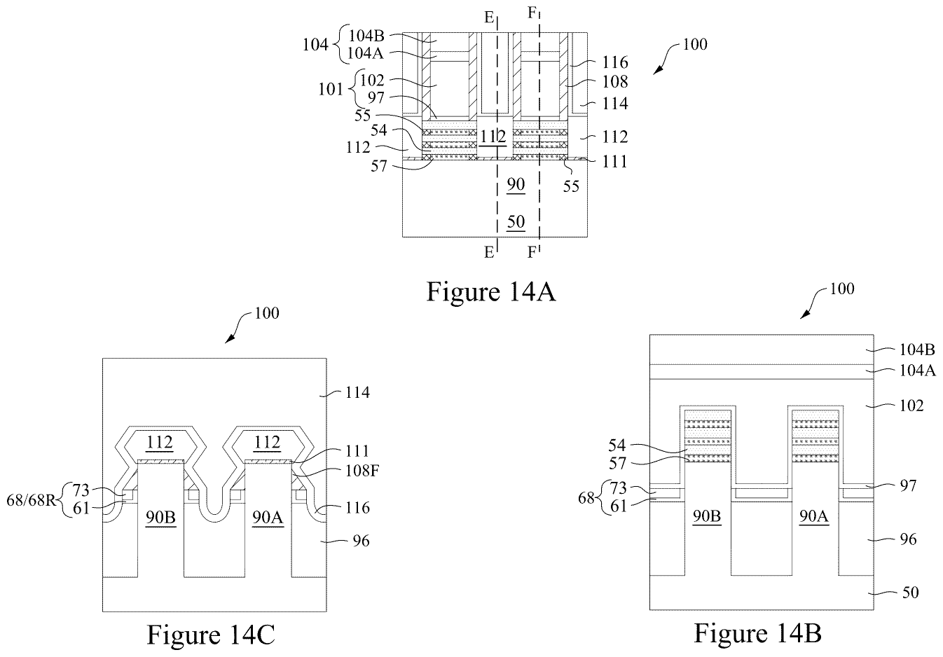

As a result of the epitaxy processes used to form the epitaxial source/drain regions 112, upper surfaces of the epitaxial source/drain regions 112 have facets which expand laterally outward beyond sidewalls of the fins 90. In some embodiments, adjacent epitaxial source/drain regions 112 over adjacent fins 90 remain separated after the epitaxy process is completed (see, e.g., FIG. 14C). In other embodiments, these facets cause adjacent epitaxial source/drain regions 112 to merge.

Next, in FIGS. 14A-14C, a contact etch stop layer (CESL) 116 is formed (e.g., conformally) over the source/drain regions 112 and over the dummy gate 102, and a first inter-layer dielectric (ILD) 114 is then deposited over the CESL 116. Note that for simplicity, the source/drain regions 112 in FIGS. 14A-14C (and in figures of subsequent processing steps) do not show the details of the source/drain regions, with the understanding that the details of the source/drain regions 112 are illustrated in, e.g., FIG. 13.

The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may also be used.

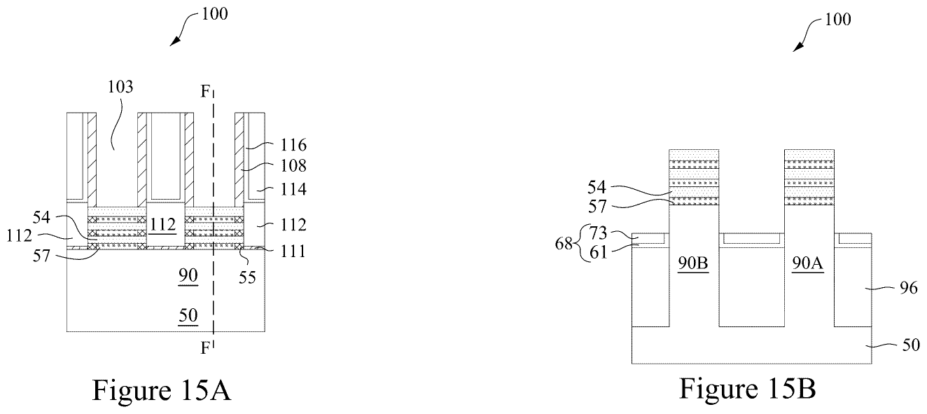

FIGS. 15A, 15B, 16A, 16B, 17A, and 17B illustrate a replacement gate process performed subsequently, where the dummy gate structures 101 are removed and replaced by replacement gate structures 123 (e.g., metal gate structures). The cross-sectional views corresponding to FIG. 14C are not illustrated for the replacement gate process, because such cross-sectional views are the same as FIG. 14C, in some embodiments.

Next, in FIGS. 15A and 15B, the dummy gates 102 are removed in an etching step(s), so that recesses 103 (may also be referred to as gate trenches) are formed between respective gate spacers 108. In some embodiments, the dummy gates 102 are removed by an anisotropic dry etching process. For example, the etching process may include a dry etching process using reaction gas(es) that selectively etch the dummy gates 102 without etching the first ILD 114 and the gate spacers 108. During the removal of the dummy gates 102, the dummy gate dielectric 97 may be used as an etch stop layer when the dummy gates 102 are etched. The dummy gate dielectric 97 may then be removed after the removal of the dummy gates 102, using, e.g., an isotropic etching process. As illustrated in FIGS. 15A and 15B, each recess 103 exposes underlying channel regions of the NSFET. Each channel region is disposed between neighboring pairs of the epitaxial source/drain regions 112.

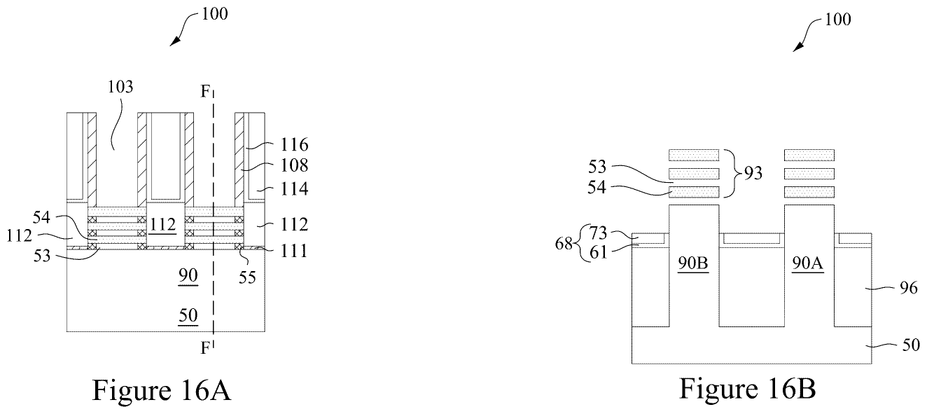

Next, in FIGS. 16A and 16B, the disposable material 57 is removed to release the second semiconductor material 54 to form nanostructure (e.g., nanosheets), and this process may be referred to as the sheet formation process. After the disposable material 57 is removed, the second semiconductor material 54 (e.g., portions underlying the dummy gate structures 101 before the dummy gate structures 101 are removed) forms a plurality of nanostructures 54 that extend horizontally (e.g., parallel to a major upper surface of the substrate 50). In some embodiments, the nanostructures 54 are nanosheets or nanowires, depending on, e.g., the dimensions (e.g., size and/or aspect ratio) of the nanostructures 54. Each nanostructure 54 may be referred to as a channel region or a channel layer of the NSFET device 100, and the nanostructures 54 may be collectively referred to as the channel regions 93 (or channel layers) of the NSFET device 100. As illustrated in FIGS. 16A and 16B, gaps 53 (e.g., empty spaces) are formed between the nanostructures 54 and between the lowermost nanostructure 54 and the fins 90 by the removal of the disposable material 57.

In some embodiments, the disposable material 57 is removed by a selective etching process using an etchant that is selective to (e.g., having a higher etch rate for) the disposable material 57, such that the disposable material 57 is removed without substantially attacking the second semiconductor material 54. In some embodiments, an isotropic etching process, such as a wet etching process or the like, is performed to remove the disposable material 57. In embodiments where the disposable material 57 include, e.g., SiO₂, and the second semiconductor material 54 include, e.g., Si or SiC, hydrogen fluoride, diluted hydrogen fluoride, another fluorine-based etchant, or the like, may be used to remove the disposable material 57.

In some embodiments, a high etching selectivity of 10,000 or more is achieved between the disposable material 57 and the second semiconductor material 54. In other words, the disposable material 57 is removed by the isotropic etching process at an etching rate 10,000 times or more than the etching rate of the second semiconductor material 54. As a result, the etching process (e.g., the sheet formation process) used to remove the disposable material 57 cause little or no damage to the nanostructures 54.

In some embodiments, both the disposable material 57 and the STI regions 96 are formed of an oxide (e.g., silicon oxide). Without the STI protection structure 68, the sheet formation process may remove upper portions of the STI regions 96 disposed under the recess 103, thus causing recessing of the STI regions 96. The recessing of the STI regions 96 reduces the distance between the subsequent formed replacement gate structure and the substrate. In addition, without the STI protection structure 68, corner regions of the STI regions 96 (e.g., regions where the upper surfaces of the STI regions 96 contact the sidewalls of the fins 90) may be removed (e.g., etched away) at a faster rate than other regions of the STI regions 96 during the sheet formation process. When the subsequently formed replacement gate structure fills the removed corner regions of the STI regions 96, protrusion of the replacement gate structure occurs. The reduced distance between the replacement gate structure and the substrate, as well as the protrusion of the replacement gate structure, cause an increase in the parasitic capacitance of the replacement gate structure. The present disclosure, by forming the STI protection structure 68, prevents or reduces the likelihood of STI region loss during the sheet formation process, thus reducing the parasitic capacitance of the NSFET device formed and improving the device performance.

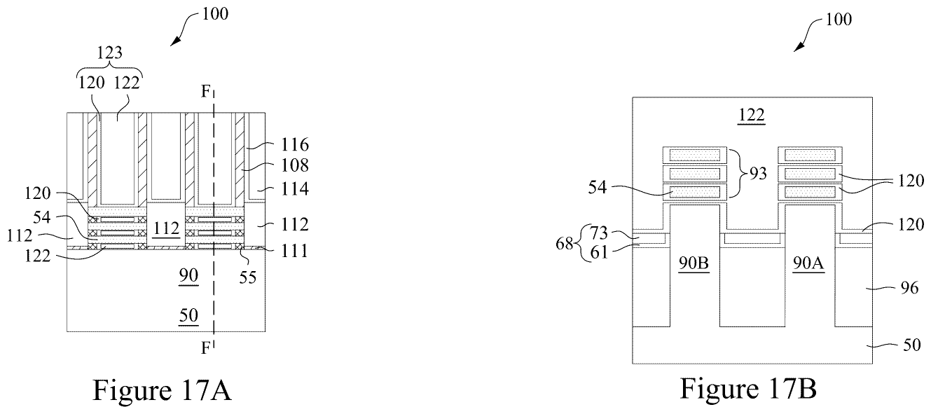

Next, in FIGS. 17A and 17B, gate dielectric layers 120 and gate electrodes 122 are formed to form replacement gate structures 123. In some embodiments, a gate dielectric material 120 is deposited conformally in the recesses 103, such as on the top surfaces and the sidewalls of the fins 90, and on sidewalls of the gate spacers 108. The gate dielectric material 120 may also be formed on the top surface of the first ILD 114. Notably, the gate dielectric material 120 is formed to wrap around the nanostructures 54. In accordance with some embodiments, the gate dielectric material 120 comprises silicon oxide, silicon nitride, or multilayers thereof. In some embodiments, the gate dielectric material 120 comprises a high-k dielectric material, and in these embodiments, the gate dielectric material 120 may have a dielectric constant (e.g., K value) greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, a gate electrode material 122 is deposited over and around the gate dielectric material 120, and fill the remaining portions of the recesses 103. The gate electrode material may include a metal-containing material such as TiN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill metal material. After the filling of the gate electrode material 122, a planarization process, such as a CMP, may be performed to remove the excess portions of the gate dielectric material 120 and the gate electrode material 122, which excess portions are over the top surface of the first ILD 114. The remaining portions of the gate electrode material 122 and the gate dielectric material 120 thus form the gate electrodes 122 and the gate dielectric layers 120, respectively, of the replacement gate structures 123 of the NSFET device 100. Each gate electrode 122 and the corresponding gate dielectric layer 120 may be collectively referred to as a replacement gate structure 123, a gate structure 123, a gate stack 123, or a metal gate structure 123. Each gate structure 123 extends around the respective nanostructures 54.

Additional processing steps may be performed to complete the fabrication of the NSFET device 100, as skilled artisans readily appreciate. For example, a second ILD may be formed over the first ILD 114. Gate contact plugs and source/drain contact plugs may be formed to extend through the second ILD and/or the first ILD 114 to be electrically coupled to the gate structures 123 and the source/drain regions 112. Next, an interconnect structure, which includes multiple dielectric layers and conductive features (e.g., vias and conductive lines) formed in the multiple dielectric layers, is formed to interconnect the underlying electrical components (e.g., NSFETs) to form functional circuits. Next, external connectors (e.g., copper pillars, conductive bumps) may be formed to be electrically coupled to the interconnect structure to provide electrical connection to external electrical devices. Dicing may be performed to separate multiple NSFET devices into separate individual devices. Details are not discussed here.

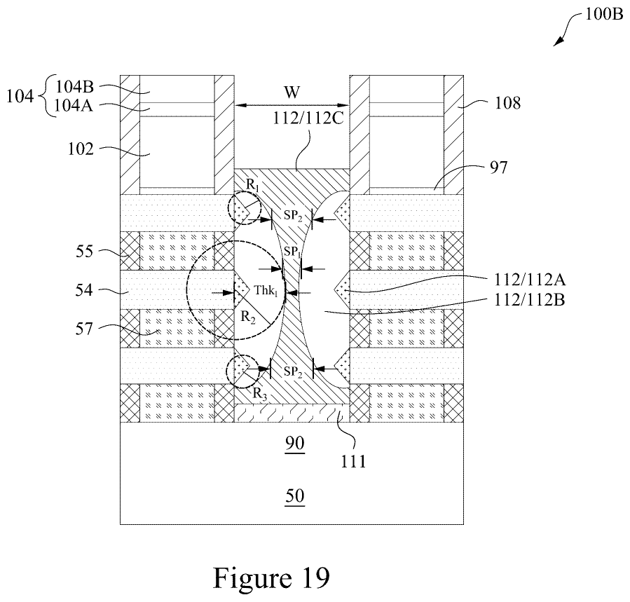

FIG. 18 illustrates a cross-sectional view of a portion of an NSFET device 100A at a certain stage of manufacturing, in accordance with an embodiment. The cross-sectional view of FIG. 18 corresponds to that of FIG. 13. The NSFET device 100A is similar to the NSFET device 100, but the epitaxial material 112B of the source/drain region 112 in the opening 110 comprises two separate portions, e.g., a left portion and a right portion that are substantially symmetric. A distance SP₁ between the left portion and the right portion may be between about 1 nm and about 20 nm, as an example. A thickness Thk₂ of the left portion (or the right portion) of the epitaxial material 112B, measured between a first sidewall of the epitaxial material 112B contacting the inner spacers 55 and a second sidewall of the epitaxial material 112B laterally distal from the inner spacers 55, is between about 1 nm and about 10 nm, and is smaller than half of the distance W between opposing sidewalls of the second semiconductor material 54, in some embodiments. FIG. 18 further illustrates additional dimensions/measurements of the epitaxial material 112B, and the values of those dimension/measurements may be the same as or similar to the dimensions/measurements with the same names in FIG. 13, thus details are not repeated here. The epitaxial material 112B in FIG. 18 may be formed using the same or similar formation process as the epitaxial material 112B in FIG. 13, with the various parameters of the reshaping process and/or the epitaxy process adjusted to achieve the shape of FIG. 18, as skilled artisans readily appreciate. The cross-sectional views of the NSFET device 100A with the replacement gate structures 123 are the same as or similar to those in FIGS. 17A and 17B, with the understanding that details of the source/drain regions 112 are shown in FIG. 18. FIG. 19 illustrates a cross-sectional view of a portion of an

NSFET device 100B at a certain stage of manufacturing, in accordance with an embodiment. The cross-sectional view of FIG. 19 corresponds to that of FIG. 13. The NSFET device 100B is similar to the NSFET device 100A, e.g., the epitaxial material 112B of the source/drain region 112 in FIG. 19 also comprises two separate portions, e.g., a left portion and a right portion that are substantially symmetric. However, unlike FIG. 18, the left portion and the right portion of the epitaxial material 112B in FIG. 19 has curved (e.g., rounded) exterior surfaces distal from the inner spacers 55, instead of the liner surfaces of the epitaxial material 112B in FIG. 18. In some embodiments, a radius R₁ of the top corner portion of the left portion (or the right portion) of the epitaxial material 112B is between about 3 nm and about 10 nm. In some embodiments, a radius R₂ of a middle portion of the left portion (or the right portion) of the epitaxial material 112B is between about 10 nm and about 25 nm. In some embodiments, a radius R₃ of the lower corner portion of the left portion (or the right portion) of the epitaxial material 112B is between about 3 nm and about 10 nm. A smallest distance SP₁ between the left portion and the right portion may be between about 1 nm and about 5 nm, as an example. A distance SP₂ between the left portion and the right portion, measured at locations proximate to the topmost inner spacer 55 or the lowermost inner spacer 55, may be between about 5 nm and about 20 nm, as an example. A largest thickness Thk₁ of the left portion (or the right portion) of the epitaxial material 112B is between about 1 nm and about 10 nm, and is smaller than half of the distance W between opposing sidewalls of the second semiconductor material 54, in some embodiments. The epitaxial material 112B in FIG. 19 may be formed using the same or similar formation process as the epitaxial material 112B in FIG. 18, with the various parameters of the reshaping process adjusted to achieve the shape of FIG. 19, as skilled artisans readily appreciate. The cross-sectional views of the NSFET device 100B with the replacement gate structures 123 are the same as or similar to those in FIGS. 17A and 17B, with the understanding that details of the source/drain regions 112 are shown in FIG. 19.

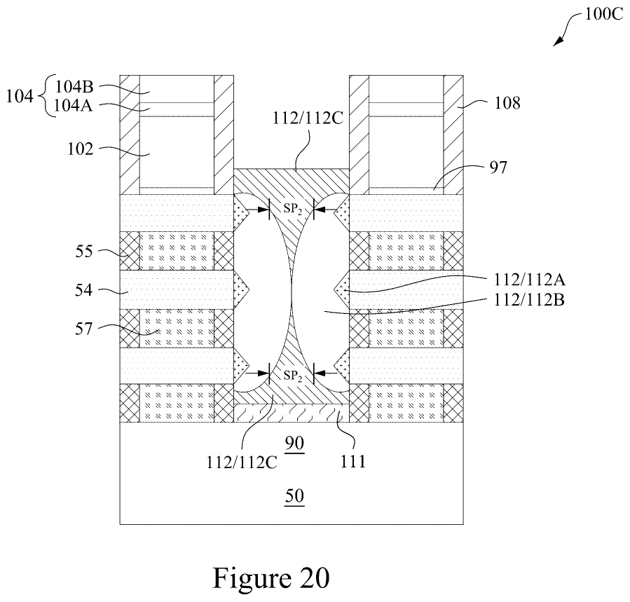

FIG. 20 illustrates a cross-sectional view of a portion of an NSFET device 100C at a certain stage of manufacturing, in accordance with an embodiment. The cross-sectional view of FIG. 20 corresponds to that of FIG. 13. The NSFET device 100C is similar to the NSFET device 100B, but the left portion and the right portion of the epitaxial material 112B in FIG. 20 merge together (e.g., in contact with each other). In FIG. 20, a distance SP₂ between the left portion and the right portion of the epitaxial material 112B, measured at locations proximate to the topmost inner spacer 55 or the lowermost inner spacer 55, may be between about 5 nm and about 20 nm, as an example. The epitaxial material 112B in FIG. 20 may be formed using the same or similar formation process as the epitaxial material 112B in FIG. 19, with the various parameters of the reshaping process adjusted to achieve the shape of FIG. 20, as skilled artisans readily appreciate. The cross-sectional views of the NSFET device 100C with the replacement gate structures 123 are the same as or similar to those in FIGS. 17A and 17B, with the understanding that details of the source/drain regions 112 are shown in FIG. 20.

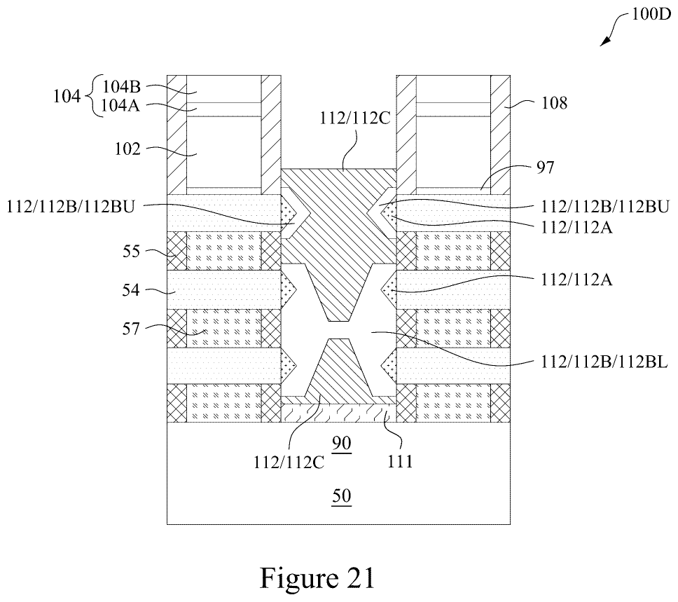

FIG. 21 illustrates a cross-sectional view of a portion of an NSFET device 100D at a certain stage of manufacturing, in accordance with an embodiment. The cross-sectional view of FIG. 21 corresponds to that of FIG. 13. The NSFET device 100D is similar to the NSFET device 100A, but with an upper portion 112BU of the epitaxial material 112B (e.g., disposed along upper sidewalls of the opening 110) comprising discrete portions, and with a lower portion 112BL of the epitaxial material 112B (e.g., disposed along lower sidewalls of the opening 110) comprising one continuous structure that extends from a first sidewall of the opening 110 to a second opposing sidewall of the opening 110. In other words, the epitaxial material 112B comprises an upper portion 112BU that includes discrete portions (e.g., spaced apart from each other) that cover exterior surfaces of respective discrete portions of the epitaxial material 112A. In addition, the epitaxial material 112B comprises a lower portion 112BL that extends continuously along the sidewalls of the opening 110, e.g., from a first discrete portion of the epitaxial material 112A to a second discrete portion of the epitaxial material 112A, and from a first sidewall of the opening 110 to a second opposing sidewall of the opening 110. The epitaxial material 112B in FIG. 21 may be formed using the same or similar formation process as the epitaxial material 112B in FIG. 18 or FIG. 12, with the various parameters of the reshaping process and/or the epitaxial process adjusted to achieve the shape of FIG. 21, as skilled artisans readily appreciate. For example, to form the epitaxial material 112B in FIG. 21, the parameters of the epitaxy process for growing the epitaxial material 112B may be tuned to have a higher growth rate at a lower portion of the source/drain opening 110 than at an upper portion of the source/drain opening 110 (e.g., having a gradient in the growth rate), such that the epitaxial material 112B formed at the lower portion of the source/drain opening 110 has a larger volume (e.g., is thicker) than the epitaxial material 112B formed at the upper portion of the source/drain opening 110. In addition, the reshaping process (e.g., the etching process) is tuned to have a higher etch rate at the upper portion of the source/drain opening 110 than at the lower portion of the sourced/drain opening 110 (e.g., having a gradient in the etch rate). By tuning the growth rate of the epitaxy process and the etch rate of the etching process as described above, the epitaxial material 112B with the same or similar shape as illustrated in FIG. 21 can be achieved. The cross-sectional views of the NSFET device 100D with the replacement gate structures 123 are the same as or similar to those in FIGS. 17A and 17B, with the understanding that details of the source/drain regions 112 are shown in FIG. 21.

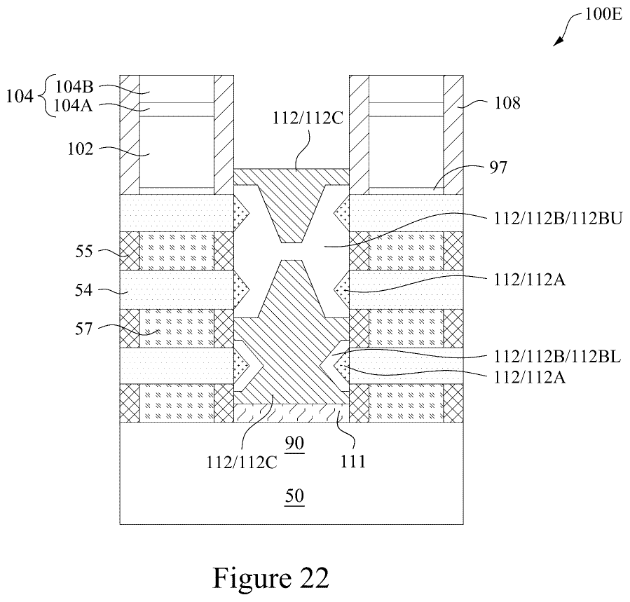

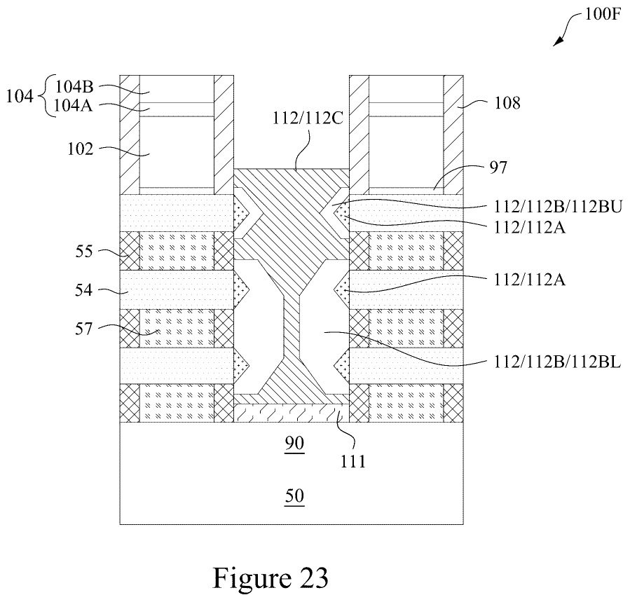

Skilled artisans will readily appreciate that by tuning the parameters of the epitaxy process and the etching process in similar ways as described above, different shapes for the epitaxial material 112B may be achieved, such as those illustrated in FIGS. 22-28 . For example, following similar epitaxy process and etching process as described above for FIG. 21, but with increased duration for the etching process may cause the lower portion 112BL to eventually break into discrete portions, thus having the same or similar shapes as illustrated in FIG. 23. As another example, by tuning the epitaxy process to have a higher growth rate at the upper portion of the source/drain opening 110 than at the lower portion of the source/drain opening 110, and by tuning the etching process to have a lower etch rate at the upper portion of the source/drain opening 110 than at the lower portion of the source/drain opening 110, the epitaxial material 112B may have a shape same as or similar to that illustrated in FIG. 22.

FIG. 22 illustrates a cross-sectional view of a portion of an NSFET device 100E at a certain stage of manufacturing, in accordance with an embodiment. The cross-sectional view of FIG. 22 corresponds to that of FIG. 13. The NSFET device 100E is similar to the NSFET device 100D, but with the lower portion 112BL of the epitaxial material 112B (e.g., disposed along lower sidewalls of the opening 110) comprising discrete portions, and with the upper portion 112BU of the epitaxial material 112B (e.g., disposed along upper sidewalls of the opening 110) comprising one continuous structure that extends from a first sidewall of the opening 110 to a second opposing sidewall of the opening 110. The epitaxial material 112B in FIG. 22 may be formed using the same or similar formation process as the epitaxial material 112B in FIG. 21, with the various parameters of the reshaping process and/or the epitaxial process adjusted to achieve the shape of FIG. 22, as skilled artisans readily appreciate. The cross-sectional views of the NSFET device 100E with the replacement gate structures 123 are the same as or similar to those in FIGS. 17A and 17B, with the understanding that details of the source/drain regions 112 are shown in FIG. 22.

FIG. 23 illustrates a cross-sectional view of a portion of an NSFET device 100F at a certain stage of manufacturing, in accordance with an embodiment. The cross-sectional view of FIG. 23 corresponds to that of FIG. 13. The NSFET device 100F is similar to the NSFET device 100D, but with the lower portion 112BL of the epitaxial material 112B (e.g., disposed along lower sidewalls of the opening 110) comprising discrete portions instead of a continuous structure. The epitaxial material 112B in FIG. 23 may be formed using the same or similar formation process as the epitaxial material 112B in FIG. 21, with the various parameters of the reshaping process and/or the epitaxial process adjusted to achieve the shape of FIG. 23, as skilled artisans readily appreciate. The cross-sectional views of the NSFET device 100F with the replacement gate structures 123 are the same as or similar to those in FIGS. 17A and 17B, with the understanding that details of the source/drain regions 112 are shown in FIG. 23.

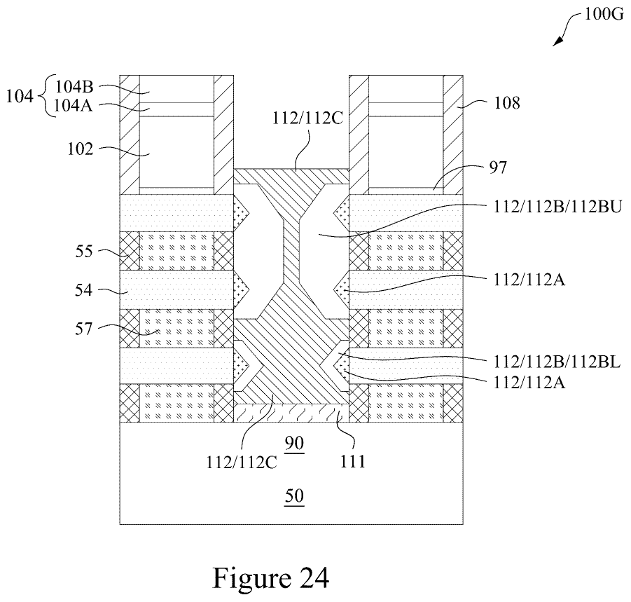

FIG. 24 illustrates a cross-sectional view of a portion of an NSFET device 100G at a certain stage of manufacturing, in accordance with an embodiment. The cross-sectional view of FIG. 24 corresponds to that of FIG. 13. The NSFET device 100G is similar to the NSFET device 100F, but with the shape of the upper portion 112BU and the lower portion 112BL of the epitaxial material 112B in FIG. 23 switched with each other. The epitaxial material 112B in FIG. 24 may be formed using the same or similar formation process as the epitaxial material 112B in FIG. 23, with the various parameters of the reshaping process and/or the epitaxial process adjusted to achieve the shape of FIG. 24, as skilled artisans readily appreciate. The cross-sectional views of the NSFET device 100G with the replacement gate structures 123 are the same as or similar to those in FIGS. 17A and 17B, with the understanding that details of the source/drain regions 112 are shown in FIG. 24.

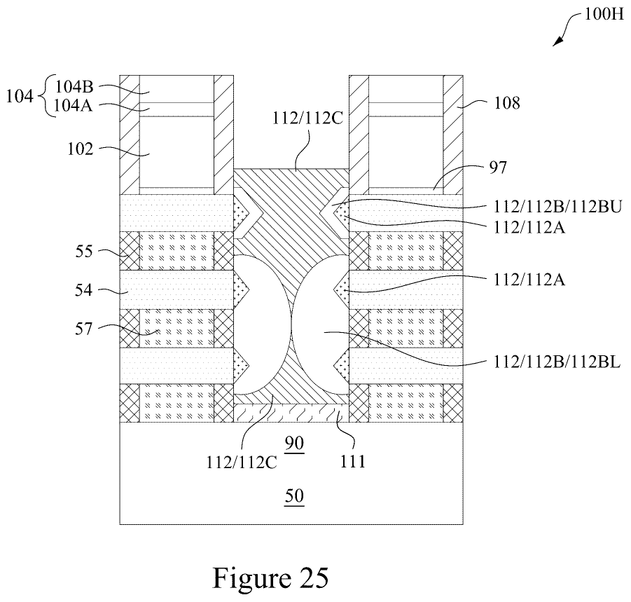

FIG. 25 illustrates a cross-sectional view of a portion of an NSFET device 100H at a certain stage of manufacturing, in accordance with an embodiment. The cross-sectional view of FIG. 25 corresponds to that of FIG. 13. The NSFET device 100H is similar to the NSFET device 100D, but with curved (e.g., rounded) exterior surfaces for the lower portion 112BL of the epitaxial material 128. The epitaxial material 112B in FIG. 25 may be formed using the same or similar formation process as the epitaxial material 112B of the NSFET device 100D, with the various parameters of the reshaping process and/or the epitaxial process adjusted to achieve the shape of FIG. 25, as skilled artisans readily appreciate. The cross-sectional views of the NSFET device 100H with the replacement gate structures 123 are the same as or similar to those in FIGS. 17A and 17B, with the understanding that details of the source/drain regions 112 are shown in FIG. 25.

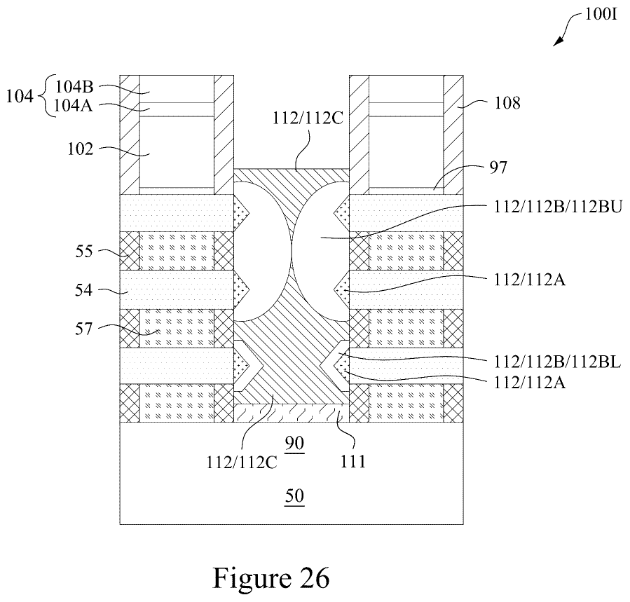

FIG. 26 illustrates a cross-sectional view of a portion of an NSFET device 100I at a certain stage of manufacturing, in accordance with an embodiment. The cross-sectional view of FIG. 26 corresponds to that of FIG. 13. The NSFET device 100I is similar to the NSFET device 100E, but with curved (e.g., rounded) exterior surfaces for the upper portion 112BU of the epitaxial material 128. The epitaxial material 112B in FIG. 26 may be formed using the same or similar formation process as the epitaxial material 112B of the NSFET device 100E, with the various parameters of the reshaping process and/or the epitaxial process adjusted to achieve the shape of FIG. 26, as skilled artisans readily appreciate. The cross-sectional views of the NSFET device 100I with the replacement gate structures 123 are the same as or similar to those in FIGS. 17A and 17B, with the understanding that details of the source/drain regions 112 are shown in FIG. 26.

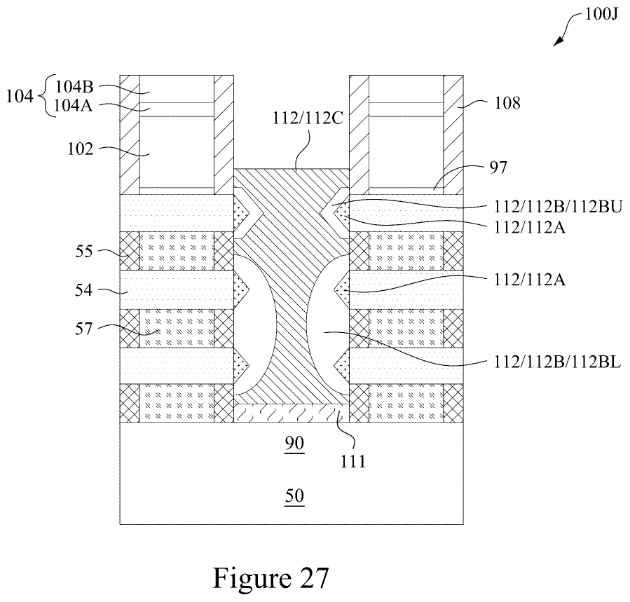

FIG. 27 illustrates a cross-sectional view of a portion of an NSFET device 100J at a certain stage of manufacturing, in accordance with an embodiment. The cross-sectional view of FIG. 27 corresponds to that of FIG. 13. The NSFET device 100J is similar to the NSFET device 100H, but with the lower portion 112BL of the epitaxial material 128 comprising discrete portions. The epitaxial material 112B in FIG. 27 may be formed using the same or similar formation process as the epitaxial material 112B of the NSFET device 100H, with the various parameters of the reshaping process and/or the epitaxial process adjusted to achieve the shape of FIG. 27, as skilled artisans readily appreciate. The cross-sectional views of the NSFET device 100J with the replacement gate structures 123 are the same as or similar to those in FIGS. 17A and 17B, with the understanding that details of the source/drain regions 112 are shown in FIG. 27.

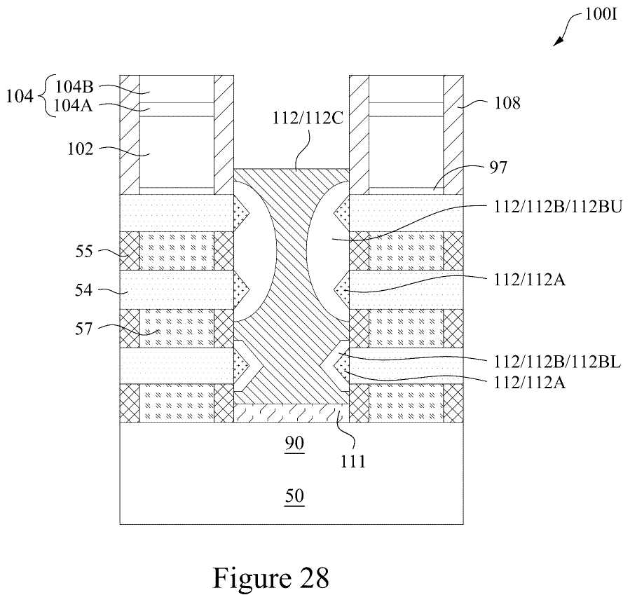

FIG. 28 illustrates a cross-sectional view of a portion of an NSFET device 100K at a certain stage of manufacturing, in accordance with an embodiment. The cross-sectional view of FIG. 28 corresponds to that of FIG. 13. The NSFET device 100K is similar to the NSFET device 100I, but with the upper portion 112BU of the epitaxial material 128 comprising discrete portions. The epitaxial material 112B in FIG. 28 may be formed using the same or similar formation process as the epitaxial material 112B of the NSFET device 100I, with the various parameters of the reshaping process and/or the epitaxial process adjusted to achieve the shape of FIG. 28, as skilled artisans readily appreciate. The cross-sectional views of the NSFET device 100K with the replacement gate structures 123 are the same as or similar to those in FIGS. 17A and 17B, with the understanding that details of the source/drain regions 112 are shown in FIG. 28.

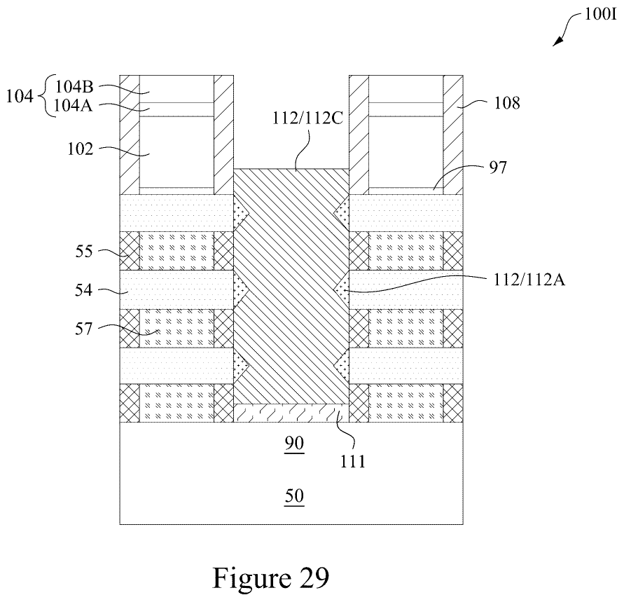

FIG. 29 illustrates a cross-sectional view of a portion of an NSFET device 100L at a certain stage of manufacturing, in accordance with an embodiment. The cross-sectional view of FIG. 29 corresponds to that of FIG. 13. The NSFET device 100L is similar to the NSFET device 100, but without the epitaxial material 112B formed in the source/drain regions 112. Therefore, the source/drain regions 112 of the NSFET device 100L has a bi-layered structure. The cross-sectional views of the NSFET device 100L with the replacement gate structures 123 are the same as or similar to those in FIGS. 17A and 17B, with the understanding that details of the source/drain regions 112 are shown in FIG. 29.

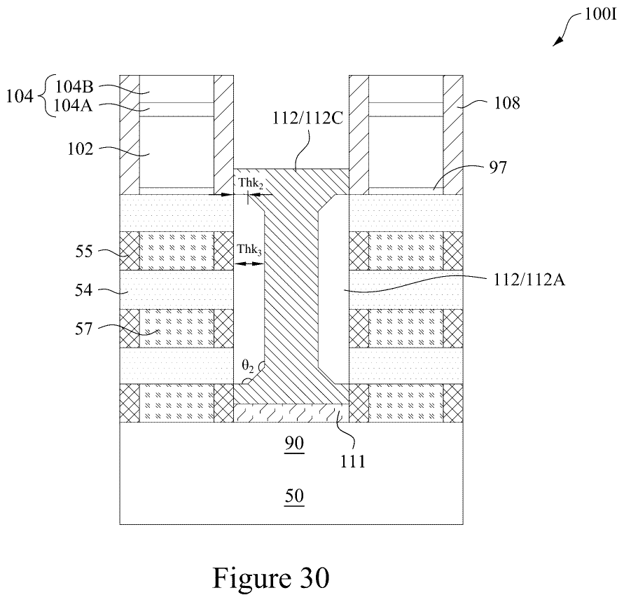

FIG. 30 illustrates a cross-sectional view of a portion of an NSFET device 100M at a certain stage of manufacturing, in accordance with an embodiment. The cross-sectional view of FIG. 30 corresponds to that of FIG. 13. The NSFET device 100M is similar to the NSFET device 100L, but the epitaxial material 112A comprises portions that extend continuously along the sidewalls of the openings 110, e.g., from a lowermost layer of the second semiconductor material 54 to an uppermost layer of the second semiconductor material 54. The cross-sectional views of the NSFET device 100M with the replacement gate structures 123 are the same as or similar to those in FIGS. 17A and 17B, with the understanding that details of the source/drain regions 112 are shown in FIG. 30.

In some embodiments, to form the epitaxial material 112A in FIG. 30, an epitaxy process same as or similar to that for forming the epitaxial material 112A in FIG. 11 is performed. The duration of the epitaxy process may be increased to increase the volume of the epitaxial material 112A formed. Next, a reshaping process is performed to reshape the epitaxial material 112A to have the shape shown in FIG. 30. In some embodiments, the reshaping process (e.g., an etching process, or a thermal anneal process) is performed with a gas source comprising a chlorine-containing gas and a silicon-containing gas, or with a gas source comprising a chlorine-containing gas and a germanium-containing gas. The silicon-containing gas may be, e.g., SiH₄ or SiH₂Cl₂. The germanium-containing gas may be, e.g., GeH₄. The chlorine-containing gas may be, e.g., HCl or Cl₂. In some embodiments, a carrier gas, such as H₂, is also used in the gas source. The reshaping process may be performed at a temperature between about 400° C. and about 1000° C., and at a pressure between about 4 torr and about 300 torr. In some embodiments, when the chlorine-containing gas is used (e.g., with a silicon-containing gas or with a germanium-containing gas), the reshaping process is referred to as an etching process (or an etch-back process). In some embodiments, the reshaping process is a thermal process performed using, e.g., H₂, and may be referred to as a thermal anneal process. In some embodiments, when the thermal anneal process is used as the reshaping process, the reshaped epitaxial material 112A tends to have curved (e.g., rounded) exterior surfaces instead of, e.g., linear exterior surfaces. Besides the above described parameters, other parameters, such as the duration of the reshaping process, may be adjusted to achieve different designed shapes for the epitaxial material 112A, as skilled artisans readily appreciate.

In the example of FIG. 30, the epitaxial material 112A in each opening 110 comprises a left portion (e.g., along a left sidewall of the opening 110) and a right portion (e.g., along a right sidewall of the opening 110) that are substantially symmetric. In the cross-sectional view of FIG. 30, the left portion (or the right portion) of the epitaxial material 112A has linear exterior surfaces. A width Thk₂ of a topmost surface (or a lowermost surface) of the left portion (or the right portion) is between about 1 nm and about 10 nm. A largest width Thk₃ of the left portion (or the right portion), measured between the sidewall of the second semiconductor material 54 and a corresponding laterally distal surface of the left portion (or the right portion), is between about 1 nm and about 10 nm. An angle θ₂ between the liner surfaces of the epitaxial material 112A is between about 90 degrees and about 180 degrees.

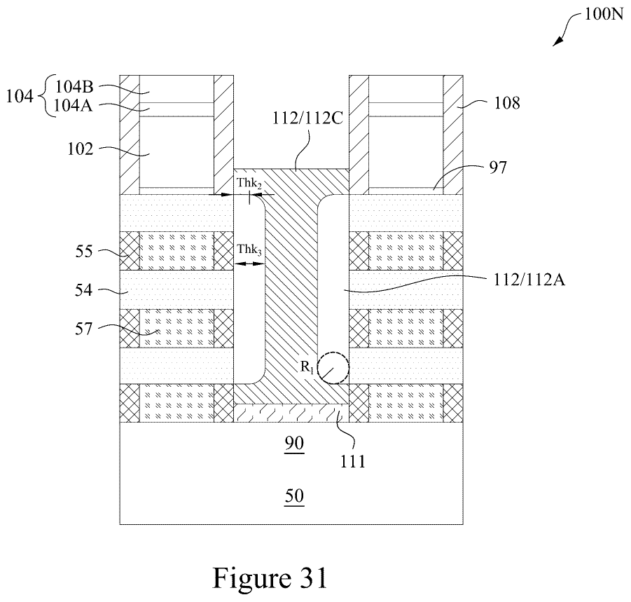

FIG. 31 illustrates a cross-sectional view of a portion of an NSFET device 100N at a certain stage of manufacturing, in accordance with an embodiment. The cross-sectional view of FIG. 31 corresponds to that of FIG. 13. The NSFET device 100N is similar to the NSFET device 100M, but the epitaxial material 112A in FIG. 31 has curved (e.g., rounded) exterior surfaces. The epitaxial material 112A in FIG. 31 may be formed by the same or similar formation process for the epitaxial material 112A in FIG. 30, but with the parameters of the reshaping process adjusted to achieve the shape of FIG. 31. The cross-sectional views of the NSFET device 100N with the replacement gate structures 123 are the same as or similar to those in FIGS. 17A and 17B, with the understanding that details of the source/drain regions 112 are shown in FIG. 31.

In FIG. 31, a radius R₁ of the top corner portion (or the bottom corner portion) of the epitaxial material 112A is between about 1 nm and about 20 nm, in some embodiments. Other dimensions of the epitaxial material 112A, such as the widths Thk₂ and Thk₃, are the same as or similar to those of the epitaxial material 112A in FIG. 30, thus details are not repeated.

Advantages are achieved by the disclosed embodiments. For example, the dielectric layer 111 formed under the source/drain regions 112 helps to reduce leakage current and reduces the parasitic capacitance of the device formed. The unique structure of the source/drain regions 112 provides enhanced channel strain to improve hole mobility in the channel regions and reduce the electrical resistance of the channel regions. In addition, the use of the DOI process reduces intermixing between germanium and silicon, and provides significantly higher etching selectivity between the disposable material 57 and the second semiconductor material 54. As a result, when the sacrificial material 57 is removed to form the nanostructures 54, there is little or no damage to the nanostructures 54. As another example, the disclosed STI protection structure 68 protects the STI regions 96 (e.g., portions directly under the dummy gates) during the sheet formation process, and as a result, loss of the STI region 96 is avoided or reduced, which reduces the parasitic capacitance of the replacement gate structure 123 and improves device performance. As yet another example, the remaining portions 68R of the STI protection structure 68 under the fin spacers 108F prevents or reduces the likelihood of the fins 90 collapsing or un-intended growth/merging of source/drain material due to over-etching of the STI regions 96 caused by the etching process used to form source/drain openings.

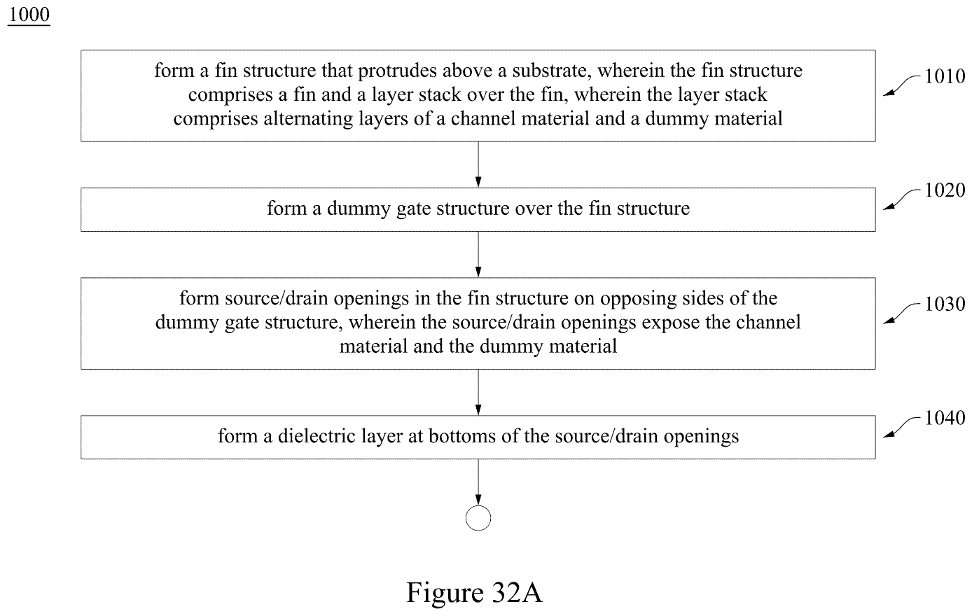

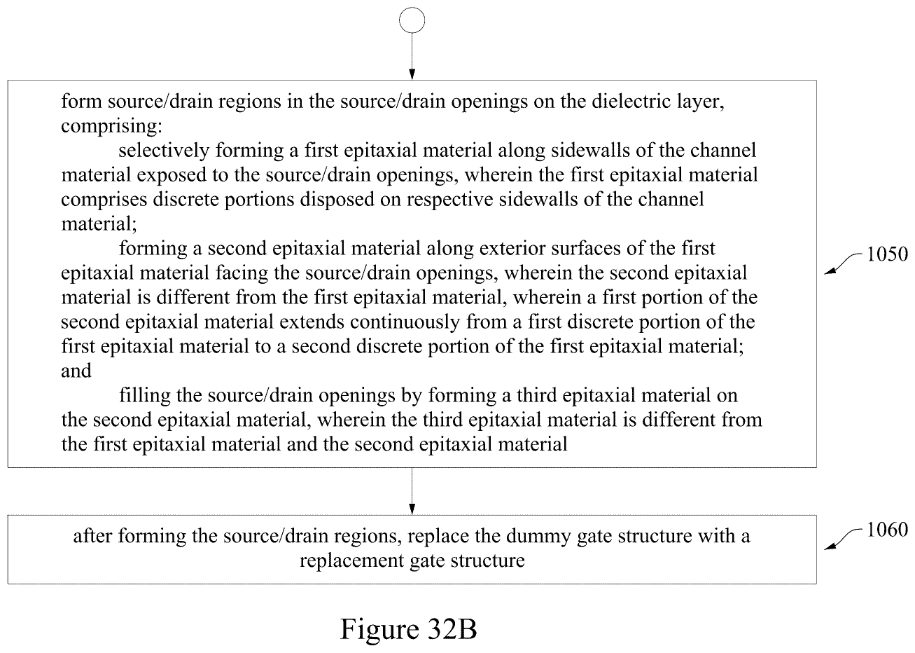

FIGS. 32A and 32B together illustrate a flow chart of a method 1000 of forming a semiconductor device, in accordance with some embodiments. It should be understood that the embodiment method shown in FIGS. 32A and 32B is merely an example of many possible embodiment methods. One of ordinary skill in the art would recognize many variations, alternatives, and modifications. For example, various steps as illustrated in FIGS. 32A and 32B may be added, removed, replaced, rearranged, or repeated.

Referring to FIGS. 32A and 32B, at block 1010, a fin structure is formed that protrudes above a substrate, wherein the fin structure comprises a fin and a layer stack over the fin, wherein the layer stack comprises alternating layers of a channel material and a dummy material. At block 1020, a dummy gate structure is formed over the fin structure. At block 1030, source/drain openings are formed in the fin structure on opposing sides of the dummy gate structure, wherein the source/drain openings expose the channel material and the dummy material. At block 1040, a dielectric layer is formed at bottoms of the source/drain openings. At block 1050, source/drain regions are formed in the source/drain openings on the dielectric layer, wherein forming the source/drain regions comprises: selectively forming a first epitaxial material along sidewalls of the channel material exposed to the source/drain openings, wherein the first epitaxial material comprises discrete portions disposed on respective sidewalls of the channel material; forming a second epitaxial material along exterior surfaces of the first epitaxial material facing the source/drain openings, wherein the second epitaxial material is different from the first epitaxial material, wherein a first portion of the second epitaxial material extends continuously from a first discrete portion of the first epitaxial material to a second discrete portion of the first epitaxial material; and filling the source/drain openings by forming a third epitaxial material on the second epitaxial material, wherein the third epitaxial material is different from the first epitaxial material and the second epitaxial material. At block 1060, after forming the source/drain regions, the dummy gate structure is replaced with a replacement gate structure.

In an embodiment, a method of forming a semiconductor device includes: forming a fin structure that protrudes above a substrate, wherein the fin structure comprises a fin and a layer stack over the fin, wherein the layer stack comprises alternating layers of a channel material and a dummy material; forming a dummy gate structure over the fin structure; forming source/drain openings in the fin structure on opposing sides of the dummy gate structure, wherein the source/drain openings expose the channel material and the dummy material; forming a dielectric layer at bottoms of the source/drain openings; and forming source/drain regions in the source/drain openings on the dielectric layer, wherein forming the source/drain regions comprises: selectively forming a first epitaxial material along sidewalls of the channel material exposed to the source/drain openings, wherein the first epitaxial material comprises discrete portions disposed on respective sidewalls of the channel material; forming a second epitaxial material along exterior surfaces of the first epitaxial material facing the source/drain openings, wherein the second epitaxial material is different from the first epitaxial material, wherein a first portion of the second epitaxial material extends continuously from a first discrete portion of the first epitaxial material to a second discrete portion of the first epitaxial material; and filling the source/drain openings by forming a third epitaxial material on the second epitaxial material, wherein the third epitaxial material is different from the first epitaxial material and the second epitaxial material. The method further includes, after forming the source/drain regions, replacing the dummy gate structure with a replacement gate structure. In an embodiment, a second portion of the second epitaxial material covers a third discrete portion of the first epitaxial material, wherein the second portion of the second epitaxial material is spaced apart from the first portion of the second epitaxial material. In an embodiment, the second epitaxial material is a semiconductor material comprising a first constituent element and a second constituent element, wherein the second epitaxial material is formed to have a first atomic ratio between the first constituent element and the second constituent element. In an embodiment, the third epitaxial material is another semiconductor material comprising the first constituent element and the second constituent element, wherein the third epitaxial material is formed to have a second atomic ratio between the first constituent element and the second constituent element, wherein the second atomic ratio is different from the first atomic ratio. In an embodiment, the first epitaxial material, the second epitaxial material, and the third epitaxial material are formed to include a same dopant. In an embodiment, the first epitaxial material is silicon doped by boron, wherein the second epitaxial material and the third epitaxial material are silicon germanium doped by boron, wherein the third epitaxial material has a higher concentration of germanium than the second epitaxial material. In an embodiment, forming the second epitaxial material comprises: performing an epitaxy process to grow the second epitaxial material on the discrete portions of the first epitaxial material; and after performing the epitaxy process, reshaping the second epitaxial material by performing an etching process or a thermal anneal process. In an embodiment, the second epitaxial material is silicon germanium doped by boron, wherein the epitaxy process is performed using a first gas source comprising a first silicon-containing precursor, a first germanium-containing precursor, and hydrogen chloride. In an embodiment, the etching process is performed using a second gas source comprising a second silicon-containing precursor and a chlorine-containing gas. In an embodiment, the etching process is performed using a second gas source comprising a second germanium-containing precursor and a chlorine-containing gas. In an embodiment, the method further comprises, after forming the source/drain openings and before forming the dielectric layer: replacing the dummy material under the dummy gate structure with a sacrificial material; and replacing end portions of the sacrificial material exposed to the source/drain openings with inner spacers. In an embodiment, replacing the dummy gate structure with the replacement gate structure comprises: removing the dummy gate structure to expose the sacrificial material and the channel material; removing the exposed sacrificial material, wherein after removing the exposed sacrificial material, the channel material remains to form channel layers of the semiconductor device; and forming a gate dielectric material and a gate electrode material around the channel layers.

In an embodiment, a method of forming a semiconductor device includes: forming a fin structure that protrudes above a substrate, wherein the fin structure comprises a fin and a layer stack over the fin, wherein the layer stack comprises alternating layers of a first semiconductor material and a second semiconductor material; forming a first dummy gate structure and a second dummy gate structure over the fin structure; forming a source/drain opening in the fin structure between the first dummy gate structure and the second dummy gate structure; after forming the source/drain opening, replacing the first semiconductor material disposed under the first dummy gat structure and the second dummy gate structure with a sacrificial material; lining a bottom of the source/drain opening with a dielectric layer; selectively forming a first epitaxial material along sidewalls of the second semiconductor material exposed by the source/drain opening, wherein the first epitaxial material comprises discrete portions disposed on respective sidewalls of the second semiconductor material; forming a second epitaxial material on the first epitaxial material, wherein a first portion of the second epitaxial material extends continuously from a first discrete portion of the first epitaxial material to a second discrete portion of the first epitaxial material; and forming a third epitaxial material on the second epitaxial material to fill the source/drain opening, wherein each of the second epitaxial material and the third epitaxial material comprises a first constituent element and a second constituent element, wherein an atomic ratio between the first constituent element and the second constituent element in the second epitaxial material is different from that in the third epitaxial material. In an embodiment, forming the second epitaxial material comprises: performing an epitaxy process to grow the second epitaxial material on the discrete portions of the first epitaxial material; and after performing the epitaxy process, reshaping the second epitaxial material by performing an etching process or a thermal anneal process. In an embodiment, the method further comprises, after forming the third epitaxial material: removing the first dummy gate structure and the second dummy gate structure to expose the sacrificial material and first portions of the second semiconductor material; removing the exposed sacrificial material, wherein after removing the exposed sacrificial material, the first portions of the second semiconductor material form channel regions of the semiconductor device; and forming a gate dielectric material and a gate electrode material around the channel regions. In an embodiment, a second portion of the second epitaxial material extends continuously from a third discrete portion of the first epitaxial material to a fourth discrete portion of the first epitaxial material, wherein the first discrete portion and the second discrete portion of the first epitaxial material are at a first side of the source/drain opening, wherein the third discrete portion and the fourth discrete portion of the first epitaxial material are at a second opposing side of the source/drain opening. In an embodiment, the first portion of the second epitaxial material are formed to merge with the second portion of the second epitaxial material. In an embodiment, the first portion of the second epitaxial material is formed to be spaced apart from the second portion of the second epitaxial material.

In an embodiment, a semiconductor device includes: a substrate; a fin protruding above the substrate; channel layers stacked vertically over the fin; a gate structure around the channel layers; and a source/drain region over the fin adjacent to the gate structure, wherein the source/drain region comprises: a first epitaxial material, wherein the first epitaxial material comprises discrete portions that are disposed along sidewalls of the channel layers; a second epitaxial material on the first epitaxial material, wherein a first portion of the second epitaxial material extends continuously from a first discrete portion of the first epitaxial material to a second discrete portion of the first epitaxial material; and a third epitaxial material on the second epitaxial material, wherein the first epitaxial material, the second epitaxial material, and the third epitaxial material are semiconductor materials with different compositions. The semiconductor device further includes a dielectric layer disposed under the source/drain region. In an embodiment, the second epitaxial material comprises a first constituent element and a second constituent element, wherein the third epitaxial material comprises the first constituent element and the second constituent element, wherein an atomic ratio between the first constituent element and the second constituent element in the second epitaxial material is different from that in the third epitaxial material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a fin structure that protrudes above a substrate, wherein the fin structure comprises a fin and a layer stack over the fin, wherein the layer stack comprises alternating layers of a channel material and a dummy material;
forming a dummy gate structure over the fin structure;
forming source/drain openings in the fin structure on opposing sides of the dummy gate structure, wherein the source/drain openings expose the channel material and the dummy material;
forming a dielectric layer at bottoms of the source/drain openings;
forming source/drain regions in the source/drain openings on the dielectric layer, comprising:
selectively forming a first epitaxial material along sidewalls of the channel material exposed to the source/drain openings, wherein the first epitaxial material comprises discrete portions disposed on respective sidewalls of the channel material;
forming a second epitaxial material along exterior surfaces of the first epitaxial material facing the source/drain openings, wherein the second epitaxial material is different from the first epitaxial material, wherein a first portion of the second epitaxial material extends continuously from a first discrete portion of the first epitaxial material to a second discrete portion of the first epitaxial material; and
filling the source/drain openings by forming a third epitaxial material on the second epitaxial material, wherein the third epitaxial material is different from the first epitaxial material and the second epitaxial material; and
after forming the source/drain regions, replacing the dummy gate structure with a replacement gate structure.

2. The method of claim 1, wherein a second portion of the second epitaxial material covers a third discrete portion of the first epitaxial material, wherein the second portion of the second epitaxial material is spaced apart from the first portion of the second epitaxial material.

3. The method of claim 1, wherein the second epitaxial material is a semiconductor material comprising a first constituent element and a second constituent element, wherein the second epitaxial material is formed to have a first atomic ratio between the first constituent element and the second constituent element.

4. The method of claim 3, wherein the third epitaxial material is another semiconductor material comprising the first constituent element and the second constituent element, wherein the third epitaxial material is formed to have a second atomic ratio between the first constituent element and the second constituent element, wherein the second atomic ratio is different from the first atomic ratio.

5. The method of claim 4, wherein the first epitaxial material, the second epitaxial material, and the third epitaxial material are formed to include a same dopant.

6. The method of claim 5, wherein the first epitaxial material is silicon doped by boron, wherein the second epitaxial material and the third epitaxial material are silicon germanium doped by boron, wherein the third epitaxial material has a higher concentration of germanium than the second epitaxial material.

7. The method of claim 1, wherein forming the second epitaxial material comprises:
performing an epitaxy process to grow the second epitaxial material on the discrete portions of the first epitaxial material; and
after performing the epitaxy process, reshaping the second epitaxial material by performing an etching process or a thermal anneal process.

8. The method of claim 7, wherein the second epitaxial material is silicon germanium doped by boron, wherein the epitaxy process is performed using a first gas source comprising a first silicon-containing precursor, a first germanium-containing precursor, and hydrogen chloride.

9. The method of claim 8, wherein the etching process is performed using a second gas source comprising a second silicon-containing precursor and a chlorine-containing gas.

10. The method of claim 8, wherein the etching process is performed using a second gas source comprising a second germanium-containing precursor and a chlorine-containing gas.

11. The method of claim 1, further comprising, after forming the source/drain openings and before forming the dielectric layer:
replacing the dummy material under the dummy gate structure with a sacrificial material; and
replacing end portions of the sacrificial material exposed to the source/drain openings with inner spacers.

12. The method of claim 11, wherein replacing the dummy gate structure with the replacement gate structure comprises:
removing the dummy gate structure to expose the sacrificial material and the channel material;
removing the exposed sacrificial material, wherein after removing the exposed sacrificial material, the channel material remains to form channel layers of the semiconductor device; and
forming a gate dielectric material and a gate electrode material around the channel layers.

13. A method of forming a semiconductor device, the method comprising:
forming a fin structure that protrudes above a substrate, wherein the fin structure comprises a fin and a layer stack over the fin, wherein the layer stack comprises alternating layers of a first semiconductor material and a second semiconductor material;
forming a first dummy gate structure and a second dummy gate structure over the fin structure;
forming a source/drain opening in the fin structure between the first dummy gate structure and the second dummy gate structure;
after forming the source/drain opening, replacing the first semiconductor material disposed under the first dummy gat structure and the second dummy gate structure with a sacrificial material;
lining a bottom of the source/drain opening with a dielectric layer;
selectively forming a first epitaxial material along sidewalls of the second semiconductor material exposed by the source/drain opening, wherein the first epitaxial material comprises discrete portions disposed on respective sidewalls of the second semiconductor material;
forming a second epitaxial material on the first epitaxial material, wherein a first portion of the second epitaxial material extends continuously from a first discrete portion of the first epitaxial material to a second discrete portion of the first epitaxial material; and
forming a third epitaxial material on the second epitaxial material to fill the source/drain opening, wherein each of the second epitaxial material and the third epitaxial material comprises a first constituent element and a second constituent element, wherein an atomic ratio between the first constituent element and the second constituent element in the second epitaxial material is different from that in the third epitaxial material.

14. The method of claim 13, wherein forming the second epitaxial material comprises:
performing an epitaxy process to grow the second epitaxial material on the discrete portions of the first epitaxial material; and
after performing the epitaxy process, reshaping the second epitaxial material by performing an etching process or a thermal anneal process.

15. The method of claim 13, further comprising, after forming the third epitaxial material:
removing the first dummy gate structure and the second dummy gate structure to expose the sacrificial material and first portions of the second semiconductor material;
removing the exposed sacrificial material, wherein after removing the exposed sacrificial material, the first portions of the second semiconductor material form channel regions of the semiconductor device; and
forming a gate dielectric material and a gate electrode material around the channel regions.

16. The method of claim 13, wherein a second portion of the second epitaxial material extends continuously from a third discrete portion of the first epitaxial material to a fourth discrete portion of the first epitaxial material, wherein the first discrete portion and the second discrete portion of the first epitaxial material are at a first side of the source/drain opening, wherein the third discrete portion and the fourth discrete portion of the first epitaxial material are at a second opposing side of the source/drain opening.

17. The method of claim 16, wherein the first portion of the second epitaxial material are formed to merge with the second portion of the second epitaxial material.

18. The method of claim 16, wherein the first portion of the second epitaxial material is formed to be spaced apart from the second portion of the second epitaxial material.

19. A semiconductor device comprising:
a substrate;
a fin protruding above the substrate;
channel layers stacked vertically over the fin;
a gate structure around the channel layers;
a source/drain region over the fin adjacent to the gate structure, wherein the source/drain region comprises:
a first epitaxial material, wherein the first epitaxial material comprises discrete portions that are disposed along sidewalls of the channel layers;
a second epitaxial material on the first epitaxial material, wherein a first portion of the second epitaxial material extends continuously from a first discrete portion of the first epitaxial material to a second discrete portion of the first epitaxial material; and
a third epitaxial material on the second epitaxial material, wherein the first epitaxial material, the second epitaxial material, and the third epitaxial material are semiconductor materials with different compositions; and
a dielectric layer disposed under the source/drain region.

20. The semiconductor device of claim 19, wherein the second epitaxial material comprises a first constituent element and a second constituent element, wherein the third epitaxial material comprises the first constituent element and the second constituent element, wherein an atomic ratio between the first constituent element and the second constituent element in the second epitaxial material is different from that in the third epitaxial material.
